(19) United States
(12) Patent Application Publication
(10) Pub. No.: US 2026/0025969 A1
(43) Pub. Date: Jan. 22, 2026

(54) METHOD OF MANUFACTURING SEMICONDUCTOR MEMORY DEVICE

(71) Applicant: Samsung Electronics Co., Ltd., Suwon-si (KR)

(72) Inventors: Dokyoung KIM, Suwon-si (KR); Youngwook PARK, Seoul (KR); Sungjun KIM, Seoul (KR); Junhyeong PARK, Seoul (KR); Hoiyoon JUNG, Seoul (KR)

(73) Assignees: Samsung Electronics Co., Ltd., Suwon-si (KR); IUCF-HYU (Industry-University Cooperation Foundation Hanyang University), Seoul (KR)

(21) Appl. No.: 19/029,231

(22) Filed: Jan. 17, 2025

(30) Foreign Application Priority Data
Jul. 18, 2024 (KR) 10-2024-0095161

(51) Int. Cl. H10B 12/00

(52) U.S. Cl. CPC H10B 12/0335; H10B 12/315; H10B 12/33; H10B 12/482; H10B 12/485

(57) ABSTRACT

A method of manufacturing a semiconductor memory device includes preparing a substrate including a device isolation layer and a plurality of active regions defined by the device isolation layer, forming a plurality of lower electrodes electrically connected to the plurality of active regions on the substrate, forming a capacitor dielectric layer on the plurality of lower electrodes, forming an upper electrode on the capacitor dielectric layer, forming a cover insulating layer covering the upper electrode, and forming a wiring contact plug connected to the upper electrode through the cover insulating layer. The forming of the upper electrode on the capacitor dielectric layer further includes forming a metallic electrode layer covering the capacitor dielectric layer and filling all spaces among the plurality of lower electrodes, forming a lower conductive semiconductor layer covering the metallic electrode layer, and forming an upper conductive semiconductor layer covering the lower conductive semiconductor layer.

### CROSS-REFERENCE TO RELATED APPLICATION

This application is based on and claims priority under 35 U.S.C. § 119 to Korean Patent Application No. 10-2024-0095161, filed on Jul. 18, 2024, in the Korean Intellectual Property Office, the disclosure of which is incorporated by reference herein in its entirety.

### BACKGROUND

The inventive concepts relate to methods of manufacturing a semiconductor memory device, and more particularly, to methods of manufacturing a semiconductor memory device having a capacitor structure.

In accordance with the rapid development of the electronics industry and user demands, electronic devices are capable of being smaller and lighter. Therefore, high integration is desired for semiconductor memory devices used in an electronic device so that the design rule for components of the semiconductor memory devices may be reduced. Accordingly, it is difficult to secure reliability of the semiconductor memory device having the capacitor structure.

### SUMMARY

The inventive concepts relates to semiconductor memory devices having a capacitor structure capable of securing and/or improving reliability.

According to some aspects of the inventive concepts, there is provided a method of manufacturing a semiconductor memory device, including preparing a substrate including a device isolation layer and a plurality of active regions, the plurality of active regions defined by the device isolation layer, forming, over the substrate, a plurality of lower electrodes electrically connected to the plurality of active regions, forming a capacitor dielectric layer on the plurality of lower electrodes, forming, on the capacitor dielectric layer, an upper electrode, forming a cover insulating layer covering the upper electrode, and forming a wiring contact plug connected to the upper electrode through the cover insulating layer. The forming, on the capacitor dielectric layer, of the upper electrode further includes forming a metallic electrode layer covering the capacitor dielectric layer and filling all spaces among the plurality of lower electrodes, forming a lower conductive semiconductor layer covering the metallic electrode layer, and forming an upper conductive semiconductor layer covering the lower conductive semiconductor layer. Each of the lower conductive semiconductor layer and the upper conductive semiconductor layer includes a group IV compound semiconductor material including germanium (Ge), and a Ge concentration of the lower conductive semiconductor layer is lower than a Ge concentration of the upper conductive semiconductor layer.

According to some aspects of the inventive concepts, there is provided a method of manufacturing a semiconductor memory device, including preparing a substrate including a device isolation layer and a plurality of active regions, the plurality of active regions defined by the device isolation layer, forming a plurality of word lines extending in a first horizontal direction across the plurality of active regions, forming a plurality of bit lines on the plurality of active regions and extending in a second horizontal direction orthogonal to the first horizontal direction, forming a plurality of buried contacts filling lower portions of spaces among the plurality of bit lines and connected to the plurality of active regions, forming a plurality of landing pads filling upper portions of spaces among the plurality of bit lines and extending onto the plurality of bit lines, forming a plurality of lower electrodes connected to the plurality of landing pads, forming a capacitor dielectric layer on the plurality of lower electrodes, forming an upper electrode on the capacitor dielectric layer, forming a cover insulating layer covering the upper electrode, and forming a wiring contact plug connected to the upper electrode through the cover insulating layer. The forming of the upper electrode on the capacitor dielectric layer further includes forming a metallic electrode layer covering the capacitor dielectric layer, filling all spaces among the plurality of lower electrodes, and including a noble metal, forming a lower conductive semiconductor layer covering the metallic electrode layer, and forming an upper conductive semiconductor layer covering the lower conductive semiconductor layer. Each of the lower conductive semiconductor layer and the upper conductive semiconductor layer includes silicon-germanium, and a Ge concentration of the lower conductive semiconductor layer is lower than a Ge concentration of the upper conductive semiconductor layer.

According to some aspects of the inventive concepts, there is provided a method of manufacturing a semiconductor memory device, including preparing a substrate including a device isolation layer and a plurality of active regions, the plurality of active regions defined by the device isolation layer, forming a plurality of word lines extending in a first horizontal direction across the plurality of active regions, forming a plurality of bit lines extending in a second horizontal direction orthogonal to the first horizontal direction on the plurality of word lines and a plurality of direct contact conductive patterns connecting the plurality of bit lines to the plurality of active regions, forming a plurality of buried contacts filling lower portions of spaces among the plurality of bit lines and connected to the plurality of active regions, forming a landing pad material layer covering the plurality of bit lines, removing part of the landing pad material layer to define a recess and form the plurality of landing pads apart from each other with the recess therebetween and connected to the plurality of buried contacts, forming an insulating layer filling the recess, forming a plurality of capacitor structures connected to the plurality of landing pads, forming a cover insulating layer covering the plurality of capacitor structures, and forming a wiring contact plug passing through the cover insulating layer. The forming of the plurality of capacitor structures further includes forming a plurality of lower electrodes connected to the plurality of landing pads on the insulating layer and the plurality of landing pads, forming a capacitor dielectric layer on the plurality of lower electrodes, and forming an upper electrode connected to the wiring contact plug on the capacitor dielectric layer. The forming of the upper electrode on the capacitor dielectric layer further includes forming a metallic electrode layer covering the capacitor dielectric layer, filling all spaces among the plurality of lower electrodes, and including ruthenium (Ru), forming a lower conductive semiconductor layer covering the metallic electrode layer, and forming an upper conductive semiconductor layer covering the lower conductive semiconductor layer. Each of the lower conductive semiconductor layer and the upper conductive semiconductor layer includes silicon-germanium, and a Ge concentration of the lower conductive semiconductor layer is lower than a Ge concentration of the upper conductive semiconductor layer. A thickness of the lower conductive semiconductor layer is less than each of a thickness of the upper conductive semiconductor layer and a thickness of the metallic electrode layer on the capacitor dielectric layer and is equal to or greater than a thickness of the capacitor dielectric layer.

### BRIEF DESCRIPTION OF THE DRAWINGS

Example embodiments will be more clearly understood from the following detailed description taken in conjunction with the accompanying drawings in which:

FIG. 1 is a block diagram illustrating a semiconductor memory device according to some example embodiments;

FIG. 2 is a schematic plan layout for describing a semiconductor memory device according to some example embodiments;

FIGS. 3A to 3D, 4A to 4D, 5A to 5D, 6A to 6D, 7A to 7D, 8A to 8D, 9A to 9D, 10A to 10D, and 11A to 11C are cross-sectional views illustrating a method of manufacturing a 12D are cross-sectional views illustrating a semiconductor memory device according to some example embodiments;

FIGS. 13A to 13D are cross-sectional views illustrating a semiconductor memory device according to some example embodiments;

FIGS. 14A and 14B illustrate depth profiles of an example material forming an upper electrode of a semiconductor memory device according to some example embodiments;

FIGS. 15A to 15C illustrate changes in sheet resistance of an example material forming an upper electrode of a semiconductor memory device according to some example embodiments;

FIG. 16 is a layout diagram illustrating a semiconductor memory device according to some example embodiments, and FIG. 17 is a cross-sectional view taken along line X1-X1′ and line Y1-Y1′ of FIG. 16;

FIG. 18 is a layout diagram illustrating a semiconductor memory device according to some example embodiments, and FIG. 19 is a perspective view illustrating a semiconductor memory device; and

FIG. 20 is a cross-sectional view taken along line X1-X1′ and line Y1-Y1′ of FIG. 16.

### DETAILED DESCRIPTION

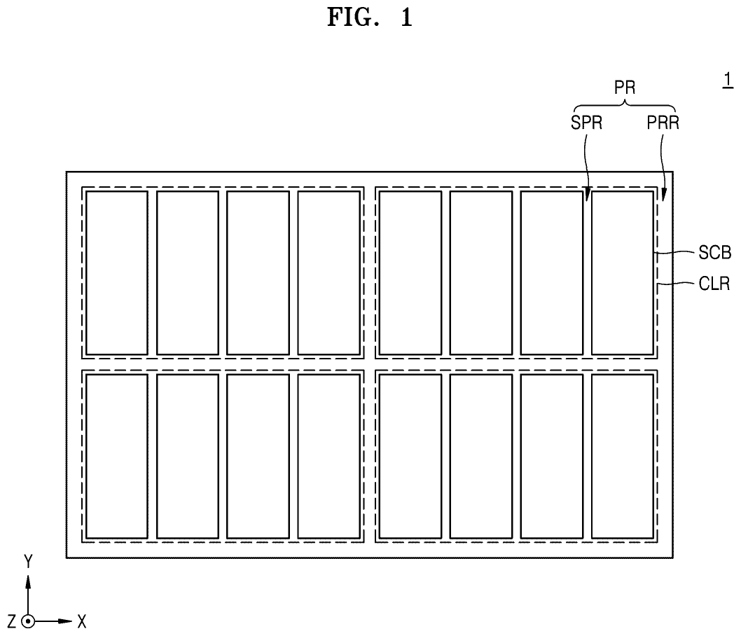

FIG. 1 is a block diagram illustrating a semiconductor memory device 1 according to some example embodiments.

Referring to FIG. 1, the semiconductor memory device 1 may include a cell region CLR in which memory cells are arranged and a main peripheral region PRR surrounding the cell region CLR.

According to some example embodiments, the cell region CLR may include sub-peripheral regions SPR distinguishing cell blocks SCB. A plurality of memory cells may be arranged in the cell blocks SCB. In the current specification, the cell block SCB may refer to a region in which the memory cells are regularly arranged at uniform intervals, and the cell block SCB may be referred to as a sub-cell block.

Logic cells for inputting/outputting electrical signals to the memory cells may be arranged in the main peripheral region PRR and the sub-peripheral region SPR. In some example embodiments, the main peripheral region PRR may be referred to as a peripheral circuit region, and the sub-peripheral region SPR may be referred to as a core circuit region. The peripheral region PR may include the main peripheral region PRR and the sub-peripheral region SPR. That is, the peripheral region PR may include the peripheral circuit region and the core circuit region. In some example embodiments, at least part of the sub-peripheral region SPR may be provided only as a space for distinguishing the cell blocks SCB.

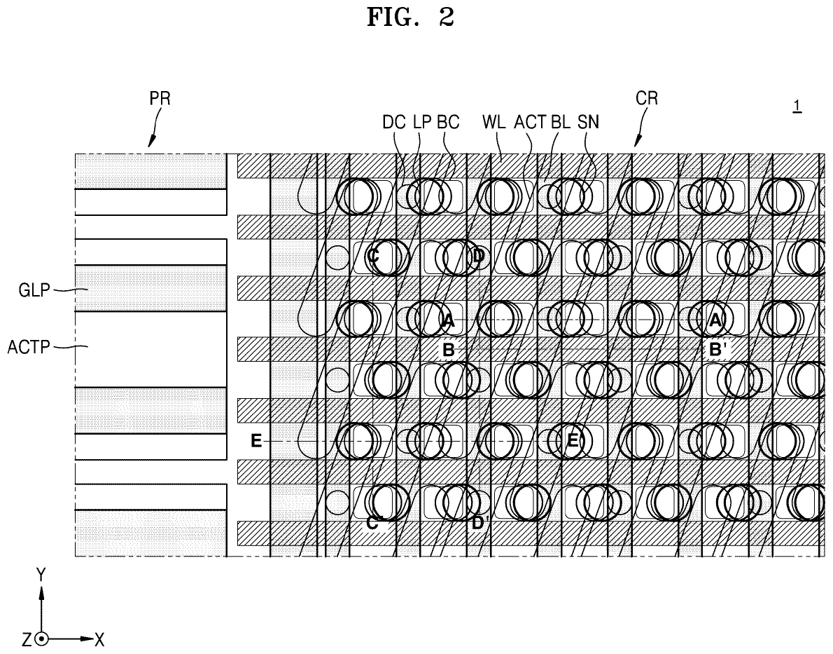

FIG. 2 is a schematic plan layout to describe a semiconductor memory device 1 according to some example embodiments.

Referring to FIG. 2, the semiconductor memory device 1 may include a memory cell region CR and a peripheral region PR. The semiconductor memory device 1 may include a plurality of active regions ACT formed in the memory cell region CR and a plurality of logic active regions ACTP formed in the peripheral region PR. The memory cell region CR may be the cell block SCB in which the plurality of memory cells illustrated in FIG. 1 are arranged, and the peripheral region PR may be the peripheral region PR including the main peripheral region PRR and the sub-peripheral regions SPR illustrated in FIG. 1.

The plurality of active regions ACT arranged in the memory cell region CR may be arranged to have long axes in an oblique direction with respect to a first horizontal direction (an X direction) and a second horizontal direction (a Y direction). In some example embodiments, the plurality of active regions ACT may be arranged in a row in an oblique direction with respect to the first horizontal direction (the X direction) and the second horizontal direction (the Y direction), and may be arranged in a row in the second horizontal direction (the Y direction).

A plurality of word lines WL may extend parallel to one another in the first horizontal direction (the X direction) across the plurality of active regions ACT in the memory cell region CR. In some example embodiments, a pair of word lines WL may extend parallel to each other in the first horizontal direction (the X direction) on one active region ACT. On the plurality of word lines WL, a plurality of bit lines BL may extend parallel to one another in the second horizontal direction (the Y direction) crossing the first horizontal direction (the X direction). In some example embodiments, one bit line BL may extend on one active region ACT in the second horizontal direction (the Y direction). The plurality of bit lines BL may be connected to the plurality of active regions ACT through a plurality of direct contacts DC. The plurality of direct contacts DC may be arranged at portions at which the plurality of bit lines BL cross the plurality of active regions ACT.

In some example embodiments, a plurality of buried contacts BC may each be formed between each two adjacent bit lines BL among the plurality of bit lines BL. In some example embodiments, the plurality of buried contacts BC may be arranged in a line in the first horizontal direction (the X direction) and the second horizontal direction (the Y direction). In some example embodiments, a pair of buried contacts BC may be connected to one active region ACT. For example, one buried contact BC may be connected to both ends of one active region ACT.

A plurality of landing pads LP may be respectively formed on the plurality of buried contacts BC. The plurality of landing pads LP may be arranged to at least partially and respectively overlap the plurality of buried contacts BC. In some example embodiments, each of the plurality of landing pads LP may extend to a top of one of two adjacent bit lines BL.

A plurality of storage nodes SN may be respectively formed on the plurality of landing pads LP. The plurality of storage nodes SN may be formed on the plurality of bit lines BL. Each of the plurality of storage nodes SN may be a lower electrode of each of a plurality of capacitors. The plurality of storage nodes SN may be connected to the plurality of active regions ACT through the plurality of landing pads LP and the plurality of buried contacts BC.

A plurality of gate line patterns GLP may be arranged on the plurality of logic active regions ACTP in the peripheral region PR. It is illustrated in FIG. 2 that the plurality of gate line patterns GLP extend parallel to one another in the first horizontal direction (the X direction) on the plurality of logic active regions ACTP and have a constant width in the second horizontal direction (the Y direction). However, the inventive concepts are not limited thereto. For example, each of the plurality of gate line patterns GLP may have various widths or change in width, may be curved, or may extend in various directions.

In FIG. 2, components other than the plurality of logic active regions ACTP and the plurality of gate line patterns GLP in the peripheral region PR are omitted for convenience of illustration. In addition, it is illustrated in FIG. 2 that the plurality of gate line patterns GLP are arranged only on the plurality of logic active regions ACTP. However, the inventive concepts are not limited thereto. For example, at least some of the plurality of gate line patterns GLP may extend outside the plurality of logic active regions ACTP.

The plurality of gate line patterns GLP may be at the same level as the plurality of bit lines BL. In some example embodiments, the plurality of gate line patterns GLP and the plurality of bit lines BL may include the same material, or at least partially include the same material. For example, a process of forming all or some of the plurality of gate line patterns GLP may be the same as a process of forming all or some of the plurality of bit lines BL.

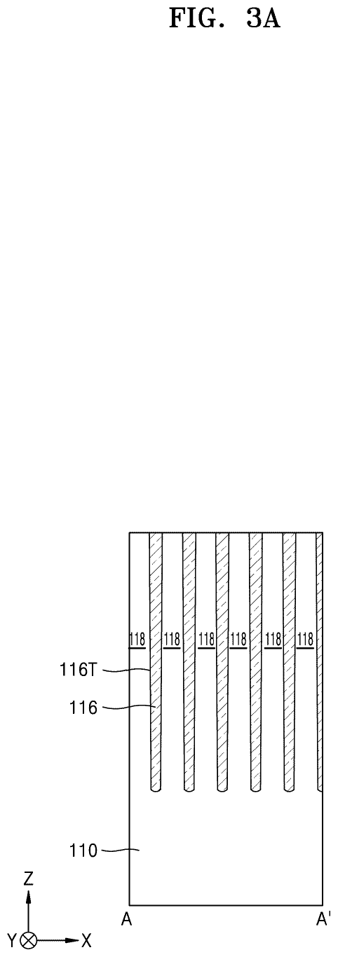

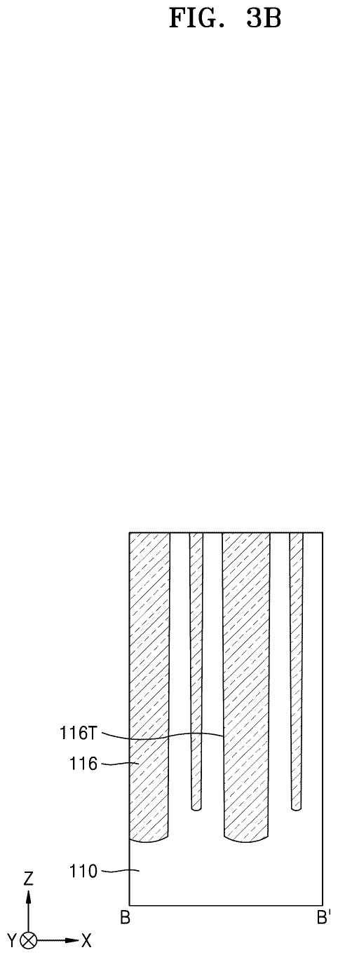

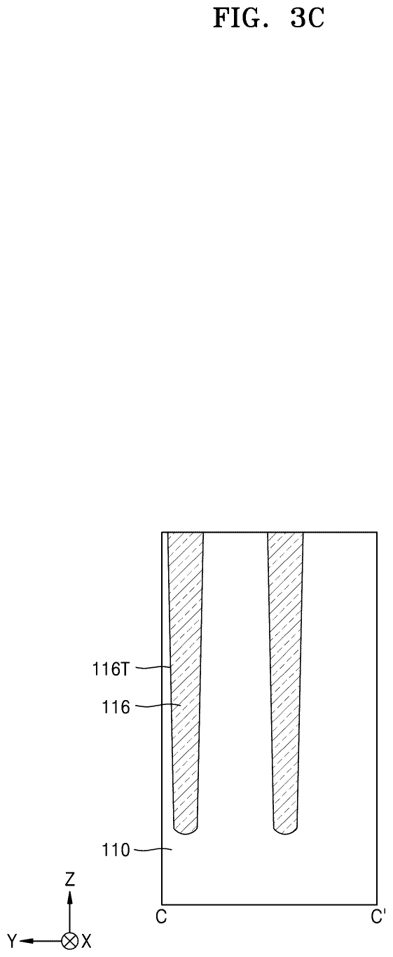

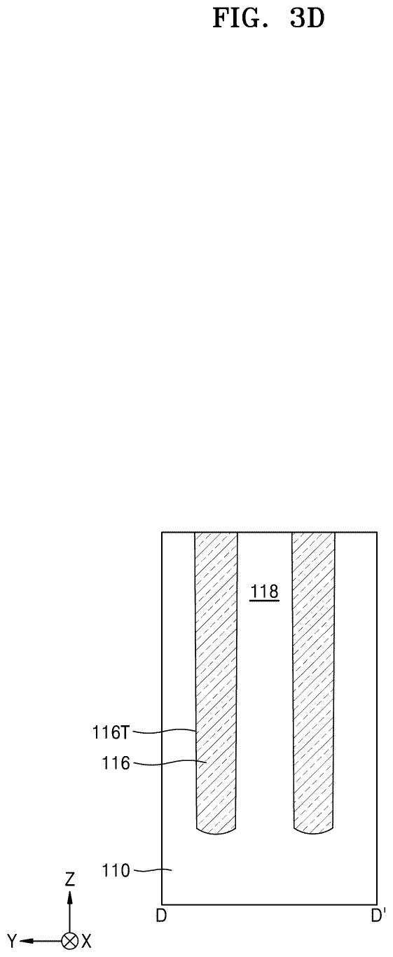

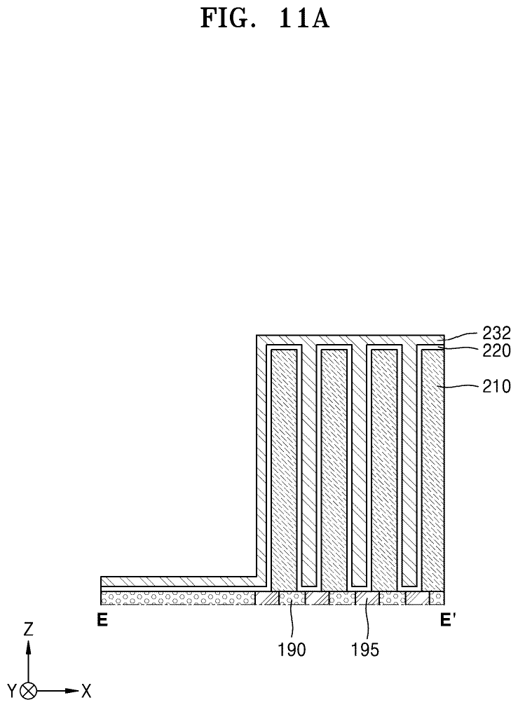

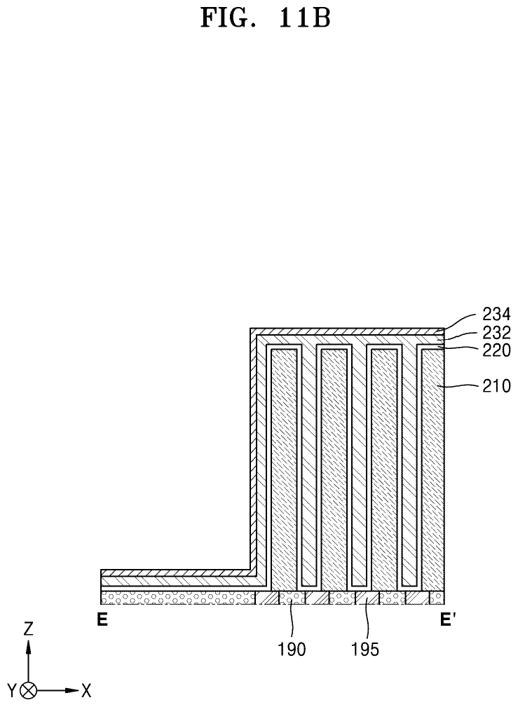

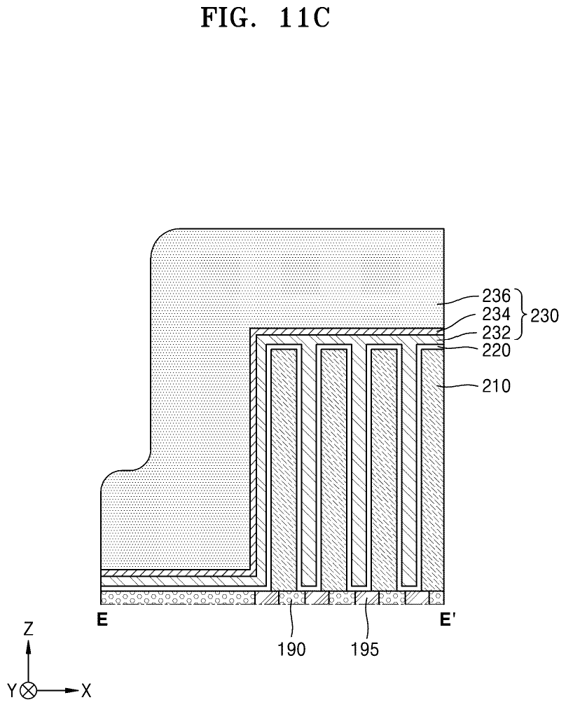

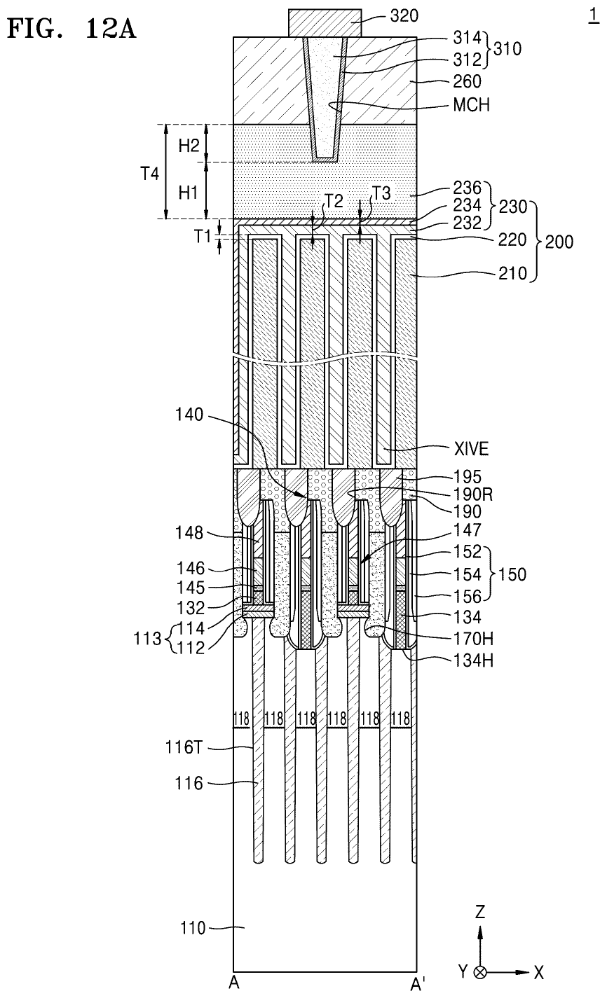

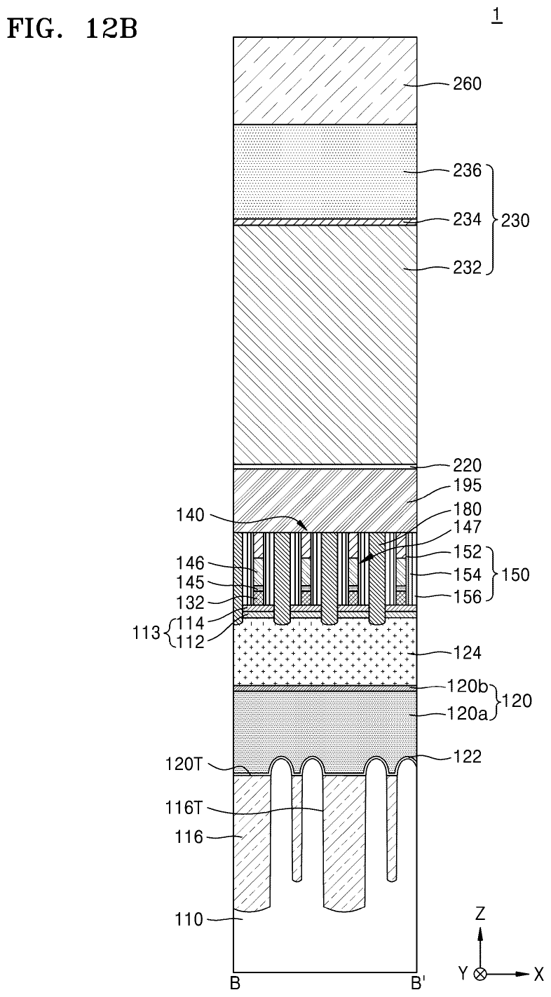

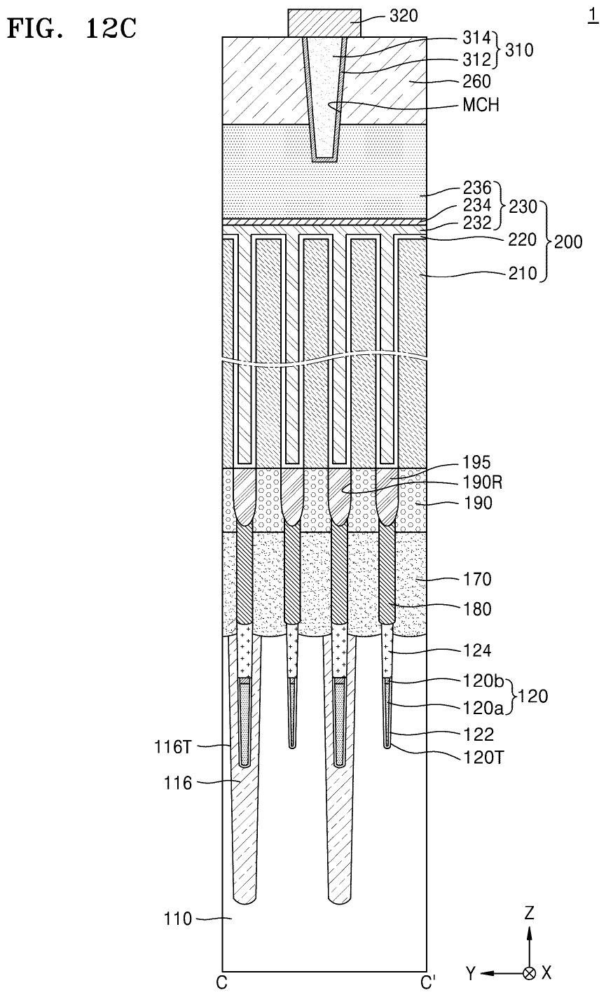

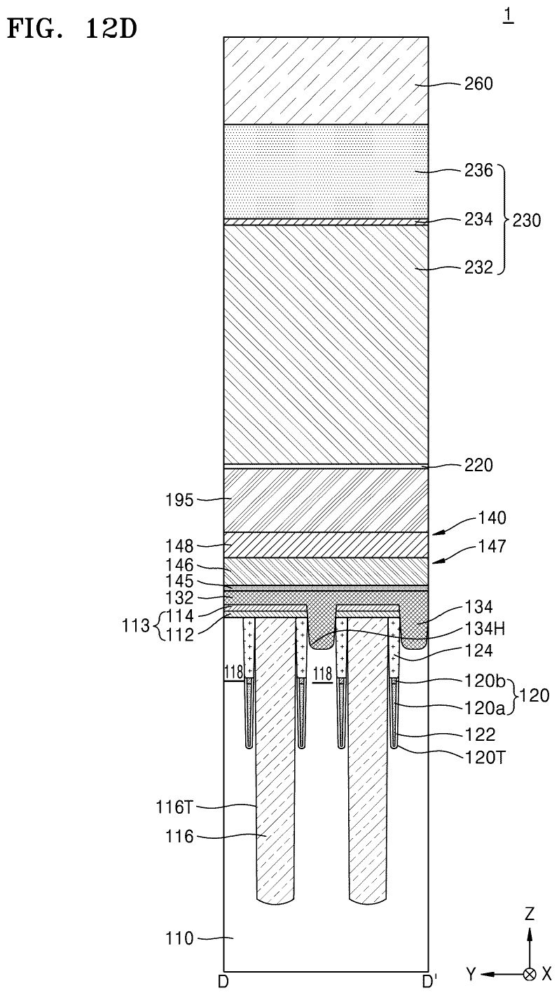

FIGS. 3A to 3D, 4A to 4D, 5A to 5D, 6A to 6D, 7A to 7D, 8A to 8D, 9A to 9D, 10A to 10D, and 11A to 11C are cross-sectional views illustrating a method of manufacturing a 12D are cross-sectional views illustrating a semiconductor memory device according to some example embodiments. Specifically, FIGS. 3A, 4A, 5A, 6A, 7A, 8A, 9A, 10A, and 12A are cross-sectional views taken along the line A-A′ of FIG. 2, FIGS. 3B, 4B, 5B, 6B, 7B, 8B, 9B, 10B, and 12B are cross-sectional views taken along the line B-B′ of FIG. 2, FIGS. 3C, 4C, 5C, 6C, 7C, 8C, 9C, 10C, and 12C are cross-sectional views taken along the line C-C′ of FIG. 2, FIGS. 3D, 4D, 5D, 6D, 7D, 8D, 9D, 10D, and 12D are cross-sectional views taken along the line D-D′ of FIG. 2, and FIGS. 11A to 11C are cross-sectional views taken along the line E-E′ of FIG. 2.

Referring to FIGS. 3A to 3D, a device isolation trench 116T may be formed in a substrate 110, and a device isolation layer 116 filling the device isolation trench 116T may be formed. In some example embodiments, the device isolation trench 116T and a plurality of active regions 118 defined by the device isolation trench 116T may be formed through an EUV lithography process.

The substrate 110 may include, for example, silicon (Si), crystalline Si, polycrystalline Si, and/or amorphous Si. In some example embodiments, the substrate 110 may include a semiconductor element such as germanium (Ge), and/or at least one compound semiconductor selected from silicon germanium (SiGe), silicon carbide (SiC), gallium arsenide (GaAs), indium arsenide (InAs), and indium phosphide (InP). In some example embodiments, the substrate 110 may have a silicon on insulator (SOI) structure. For example, the substrate 110 may include a buried oxide (BOX) layer. The substrate 110 may include a conductive region, for example, a well doped with impurities or a structure doped with impurities. The device isolation layer 116 may include, for example, at least one of silicon oxide, silicon nitride, and silicon oxynitride. The device isolation layer 116 may include a single layer including one type of insulating layer, a double layer including two types of insulating layers, or a multilayer including a combination of at least three types of insulating layers. For example, the device isolation layer 116 may include a double layer or a multilayer including an oxide film and a nitride film. However, according to the inventive concepts, a configuration of the device isolation layer 116 is not limited thereto.

A plurality of active regions 118 may be defined in the substrate 110 in the memory cell region CR by the device isolation layer 116. Each of the plurality of active regions 118 may be in the form of a long island with a short axis and a long axis in a plan view, like each of the plurality of active regions ACT illustrated in FIG. 2. The plurality of active regions 118 may be arranged in a row in an oblique direction with respect to the first horizontal direction (the X direction) and the second horizontal direction (the Y direction), and may be arranged in a row in the second horizontal direction (the Y direction).

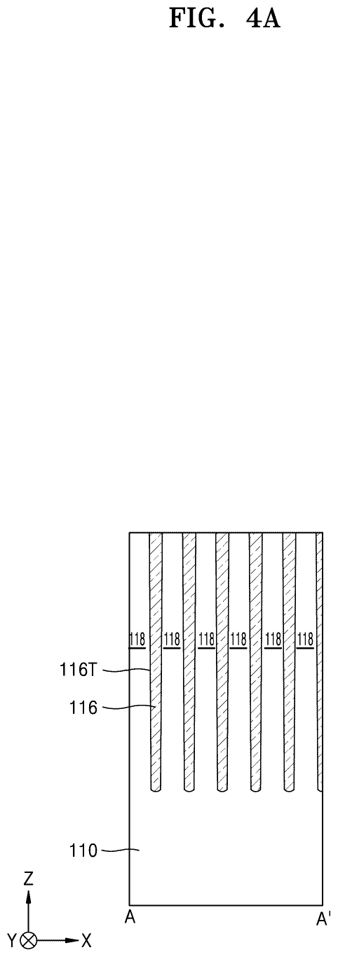

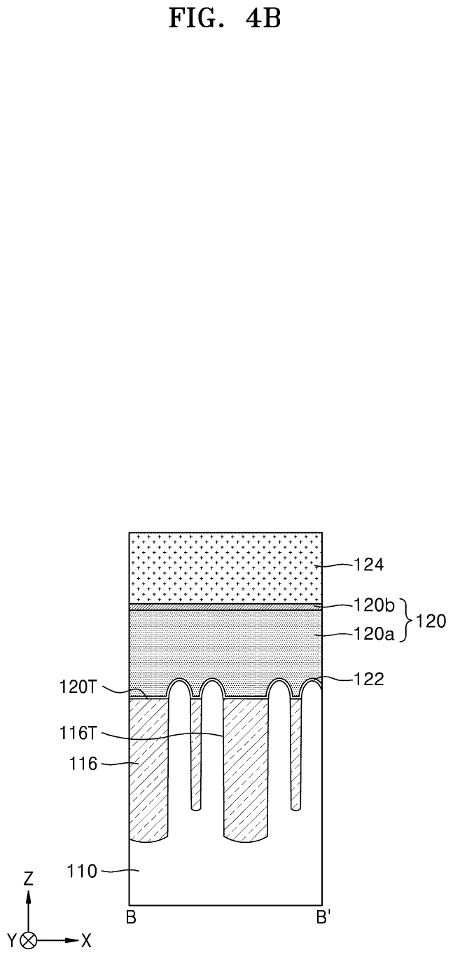

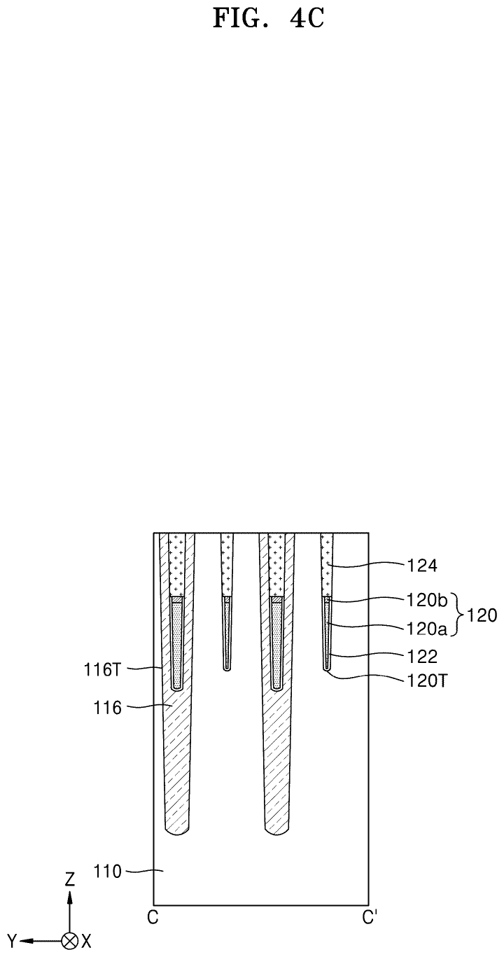

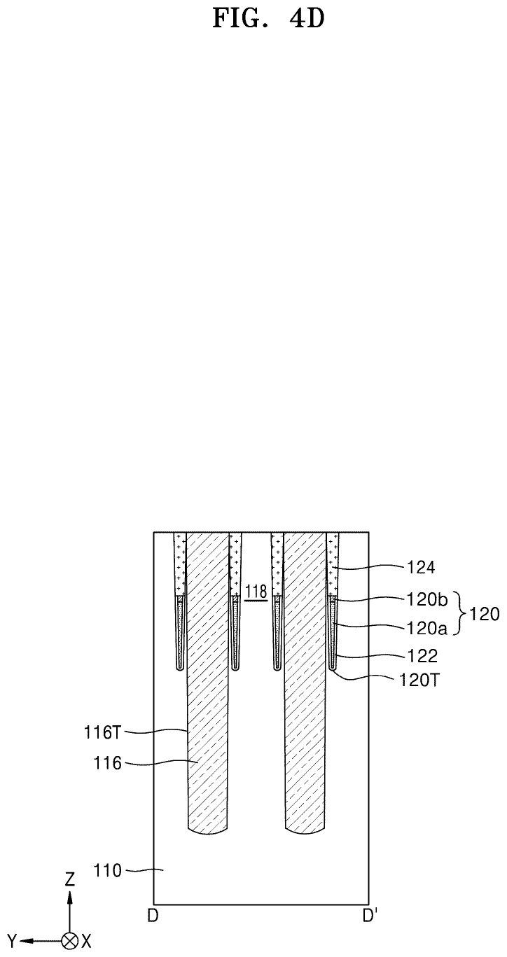

Referring to FIGS. 4A to 4D together, part of the active region 118 and part of the device isolation layer 116 are removed to form a plurality of word line trenches 120T in the substrate 110. The plurality of word line trenches 120T may extend parallel to one another in the first horizontal direction (the X direction), and may be in the form of lines crossing the plurality of active regions 118 and apart from one another at equal or substantially equal intervals in the second horizontal direction (the Y direction). In some example embodiments, steps may be formed on bottom surfaces of the plurality of word line trenches 120T.

A plurality of gate dielectric layers 122, a plurality of word lines 120, and a plurality of buried insulating layers 124 may be sequentially formed in the plurality of word line trenches 120T. The plurality of word lines 120 may respectively constitute the plurality of word lines WL illustrated in FIG. 2. The plurality of word lines 120 may extend parallel to one another in the first horizontal direction (the X direction), and may be in the form of lines crossing the plurality of active regions 118 and apart from one another at equal or substantially equal intervals in the second horizontal direction (the Y direction). A top surface of each of the plurality of word lines 120 may be at a level lower than a top surface of the substrate 110. Bottom surfaces of the plurality of word lines 120 may be concavo-convex, and saddle fin field effect transistors (FET) may be formed in the plurality of active regions 118.

Each of the plurality of word lines 120 may have a stacked structure of a lower word line layer 120a and an upper word line layer 120b. For example, the lower word line layer 120a may include a metal material, conductive metal nitride, or a combination thereof. In some example embodiments, the lower word line layer 120a may include titanium (Ti), titanium nitride (TiN), tantalum (Ta), tantalum nitride (TaN), tungsten (W), tungsten nitride (WN), titanium silicon nitride (TiSiN), tungsten silicon nitride (WSIN), or a combination thereof. For example, the upper word line layer 120b may include doped polysilicon. In some example embodiments, the lower word line layer 120a may include a core layer or a barrier layer arranged between the core layer and each of the plurality of gate dielectric layers 122.

In some example embodiments, before or after forming the plurality of word lines 120, impurity ions may be implanted into the plurality of active regions 118 of the substrate 110 on both sides of the plurality of word lines 120 to form source and drain regions in the plurality of active regions 118.

The gate dielectric layer 122 may include at least one selected from silicon oxide, silicon nitride, silicon oxynitride, oxide/nitride/oxide (ONO), and a high-k dielectric having a dielectric constant that is greater than silicon oxide. For example, each of the plurality of gate dielectric layers 122 may have a dielectric constant of about or exactly 10 to about or exactly 25.

The plurality of buried insulating layers 124 may include at least one material selected from silicon oxide, silicon nitride, silicon oxynitride, and a combination thereof.

In some example embodiments, in the process of forming the plurality of gate dielectric layers 122, the plurality of word lines 120, and the plurality of buried insulating layers 124, an upper part of the device isolation layer 116 is removed so that a top surface of the substrate 110, a top surface of the device isolation layer 116, and top surfaces of the plurality of buried insulating layers 124 may be at the same level or substantially at the same level to be coplanar.

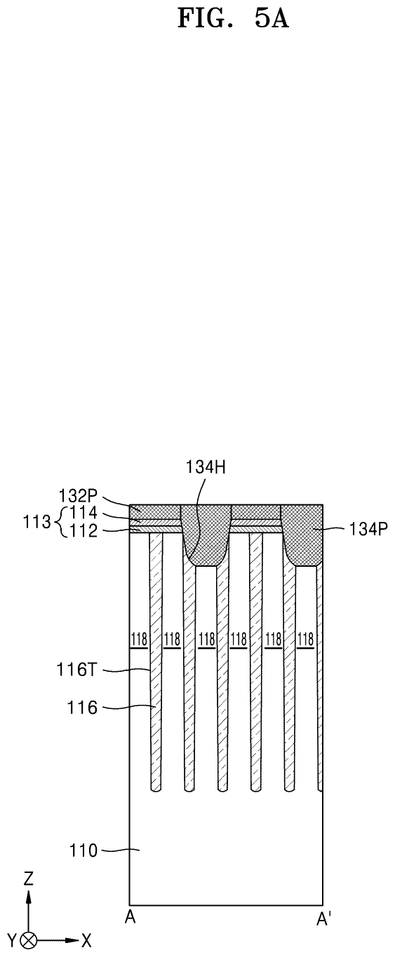

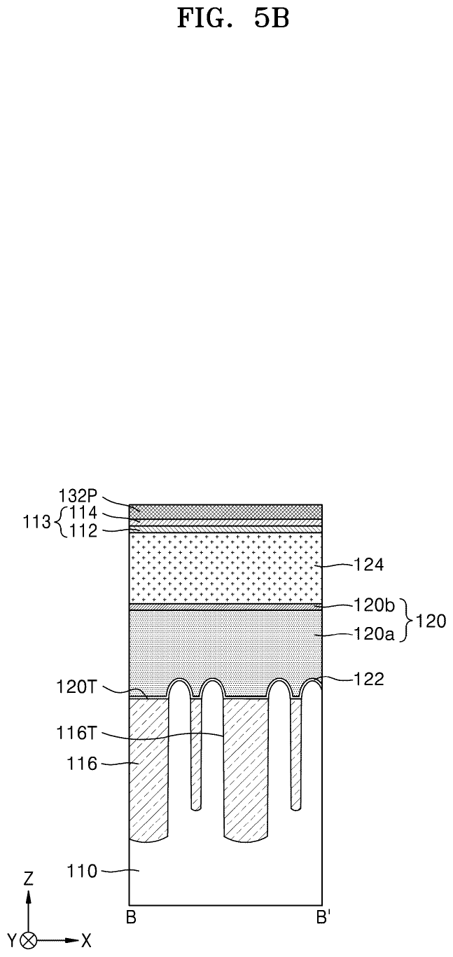

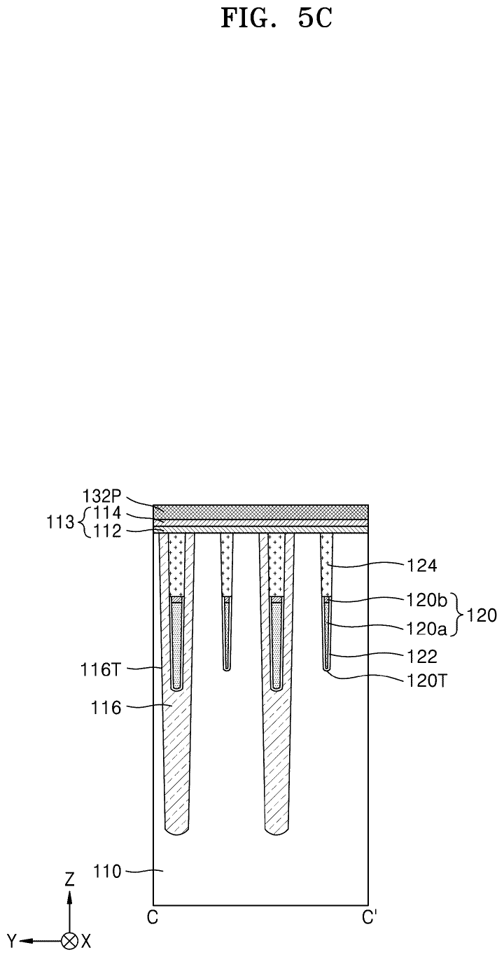

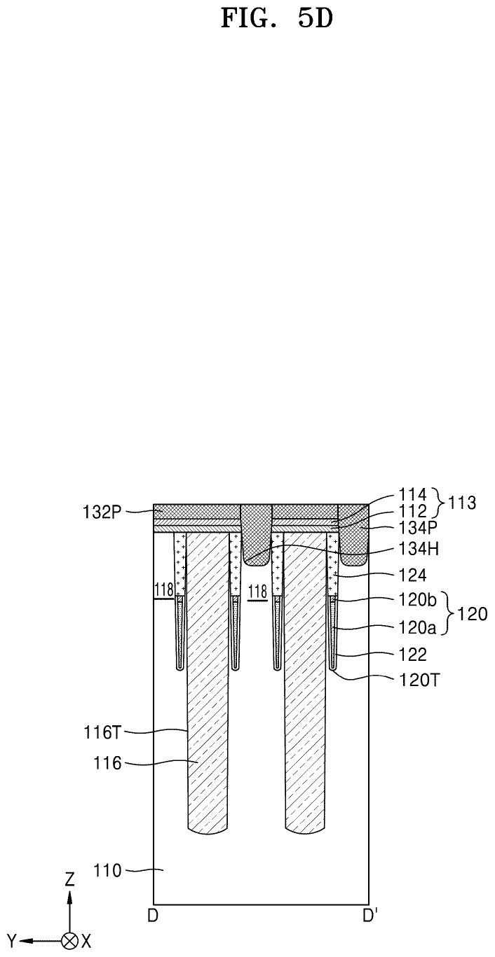

Referring to FIGS. 5A to 5D, an insulating structure 113 covering the device isolation layer 116 and the plurality of active regions 118 is formed. For example, the insulating structure 113 may include silicon oxide, silicon nitride, silicon oxynitride, a metallic dielectric, or a combination thereof. In some example embodiments, the insulating structure 113 may be formed by stacking a plurality of insulating layers including a first insulating layer pattern 112 and a second insulating layer pattern 114. In some example embodiments, the first insulating layer pattern 112 may include silicon oxide, and the second insulating layer pattern 114 may include silicon oxynitride. In some example embodiments, the first insulating layer pattern 112 may include a non-metallic dielectric layer, and the second insulating layer pattern 114 may include a metallic dielectric layer.

Then, after the conductive semiconductor layer 132P is formed on the insulating structure 113, the plurality of direct contact holes 134H passing through the conductive semiconductor layer 132P and the insulating structure 113 to expose the source regions in the plurality of active regions 118 are formed and the direct contact conductive layers 134P filling the plurality of direct contact holes 134H are formed. In some example embodiments, the plurality of direct contact holes 134H may extend into the plurality of active regions 118, that is, the source regions. The conductive semiconductor layer 132P may include, for example, doped polysilicon. In some example embodiments, the conductive semiconductor layer 132P may include the same material as the direct contact conductive layer 134P. For example, the direct contact conductive layer 134P may include doped polysilicon. In some example embodiments, the conductive semiconductor layer 132P may include a material different from the direct contact conductive layer 134P. In some example embodiments, the direct contact conductive layer 134P may include an epitaxial silicon layer, a metal, or a metal compound that is a conductive material. In some example embodiments, the direct contact conductive layer 134P may include a metal such as Ti or W, or a conductive material that is a compound of a metal such as Ti or W and a non-metal such as Si, C, B, or N. For example, the direct contact conductive layer 134P may include TIN, WC, or WSi.

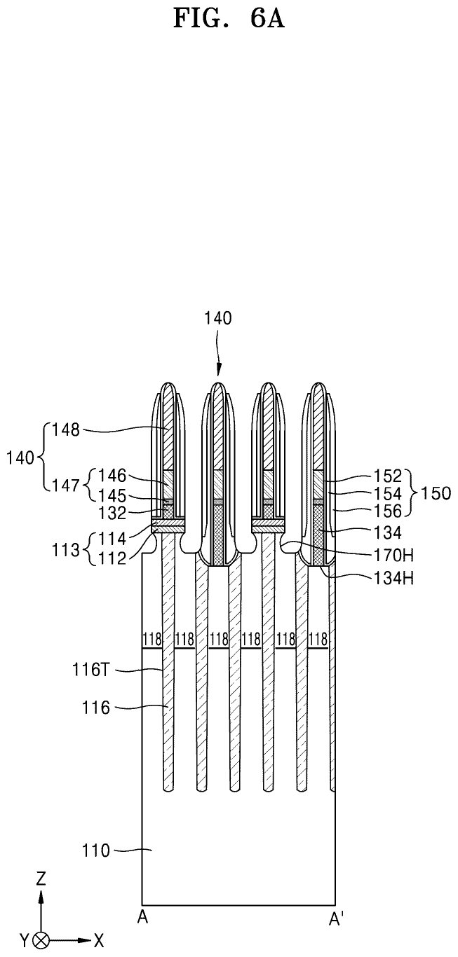

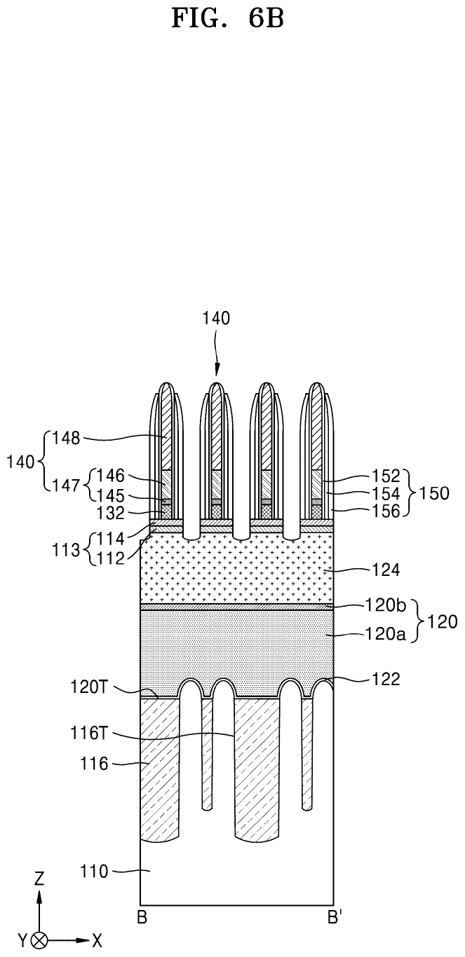

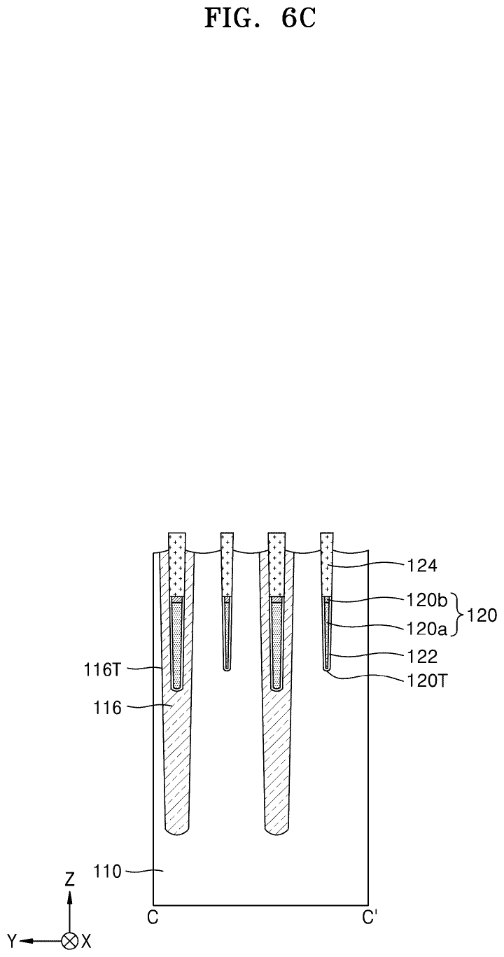

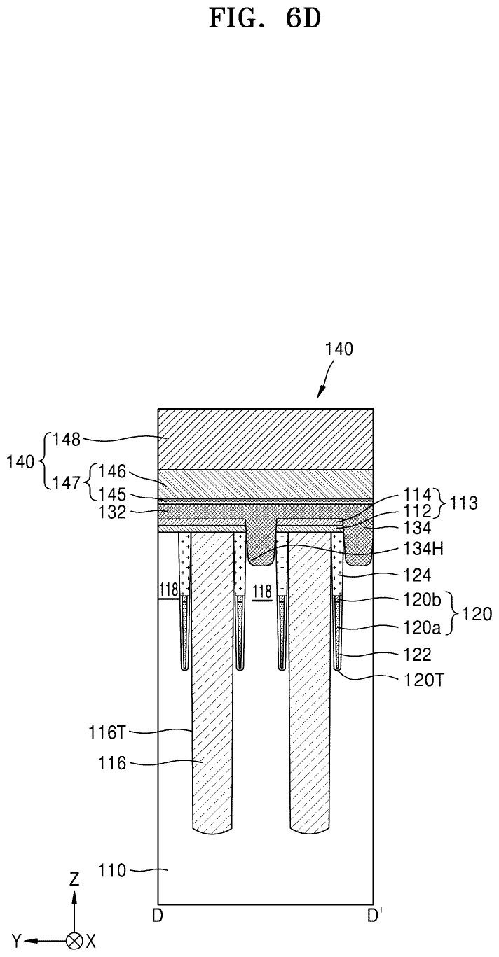

Referring to FIGS. 5A to 5D and 6A to 6D together, a metallic conductive layer and an insulation capping layer for forming the bit line structure 140 are sequentially formed to cover the conductive semiconductor layer 132P and the direct contact conductive layer 134P. In some example embodiments, the metallic conductive layer may have a stacked structure of a first metallic conductive layer and a second metallic conductive layer. The first metallic conductive layer, the second metallic conductive layer, and the insulation capping layer are etched to form a plurality of bit lines 147 each having a stacked structure of a first metallic conductive pattern 145 and a second metallic conductive pattern 146 in the form of a line, and a plurality of insulation capping lines 148 covering the plurality of bit lines 147.

In some example embodiments, the first metallic conductive pattern 145 may include TiN or Ti—Si—N(TSN) and the second metallic conductive pattern 146 may include W or W and tungsten silicide (WSix). In some example embodiments, the first metallic conductive pattern 145 may function as a diffusion barrier. In some example embodiments, the plurality of insulation capping lines 148 may include a silicon nitride film.

The plurality of bit lines 147 and the plurality of insulation capping lines 148 covering their corresponding bit lines 147 may respectively constitute a plurality of bit line structures 140. The plurality of bit line structures 140 each including a bit line 147 and an insulation capping line 148 covering the bit line 147 may extend parallel to one another in the second horizontal direction (the Y direction) parallel to a main surface of the substrate 110. The plurality of bit lines 147 may respectively constitute the plurality of bit lines BL illustrated in FIG. 2. In some example embodiments, the bit line structure 140 may further include a conductive semiconductor pattern 132 that is part of the conductive semiconductor layer 132P arranged between the insulating structure 113 and the first metallic conductive pattern 145.

The plurality of gate line patterns GLP illustrated in FIG. 2 may be formed together with the plurality of bit lines 147. For example, the plurality of gate line patterns GLP illustrated in FIG. 2 may be at the same level as the plurality of bit lines 147. In some example embodiments, the plurality of gate line patterns GLP and the plurality of bit lines 147 illustrated in FIG. 2 may include the same material or may at least partially include the same material. For example, the process of forming all or part of the plurality of gate line patterns GLP illustrated in FIG. 2 may be the same as the process of forming all or part of the plurality of bit lines 147.

In an etching process for forming the plurality of bit lines 147, a portion of the conductive semiconductor layer 132P and a portion of the direct contact conductive layer 134P, which do not vertically overlap the bit line 147, may be removed by an etching process to form a plurality of conductive semiconductor patterns 132 and a plurality of direct contact conductive patterns 134. In this case, the insulating structure 113 may function as an etching stop layer in an etching process of forming the plurality of bit lines 147, the plurality of conductive semiconductor patterns 132, and the plurality of direct contact conductive patterns 134. The plurality of direct contact conductive patterns 134 may respectively constitute the plurality of direct contacts DC illustrated in FIG. 2. The plurality of bit lines 147 may be electrically connected to the plurality of active regions 118 through the plurality of direct contact conductive patterns 134. The conductive semiconductor pattern 132 may include, for example, doped polysilicon. The direct contact conductive pattern 134 may include doped polysilicon, a metal, or a metal compound that is a conductive material. For example, the direct contact conductive pattern 134 may include a metal such as Ti or W, and/or a conductive material that is a compound of a metal such as Ti or W and a non-metal such as Si, carbon (C), boron (B), or nitrogen (N). In some example embodiments, the direct contact conductive pattern 134 may include TIN, WC, and/or WSi.

A plurality of insulating spacer structures 150 may cover side walls of the plurality of bit line structures 140. Each of the plurality of insulating spacer structures 150 may include a first insulating spacer 152, a second insulating spacer 154, and a third insulating spacer 156. The second insulating spacer 154 may include a material with a lower dielectric constant than the first insulating spacer 152 and the third insulating spacer 156. In some example embodiments, the first insulating spacer 152 and the third insulating spacer 156 may include a nitride film, and the second insulating spacer 154 may include an oxide film. In some example embodiments, the first insulating spacer 152 and the third insulating spacer 156 may include a nitride film, and the second insulating spacer 154 may include a material having etch selectivity with respect to the first insulating spacer 152 and the third insulating spacer 156. For example, when the first insulating spacer 152 and the third insulating spacer 156 include a nitride film, the second insulating spacer 154 may include an oxide film, and may be removed in a subsequent process to become an air spacer.

A plurality of buried contact holes 170H may be formed among the plurality of bit lines 147. An internal space of each of the plurality of buried contact holes 170H may be limited by the insulating spacer structure 150 covering side walls of two adjacent bit lines 147 between the two adjacent bit lines 147 among the plurality of bit lines 147 and the active region 118.

The plurality of buried contact holes 170H may be formed by removing parts of the insulating structure 113 and the plurality of active regions 118 by using the plurality of insulation capping lines 148 and the plurality of insulating spacer structures 150 covering side walls of the plurality of bit line structures 140 as etching masks. In some example embodiments, the plurality of buried contact holes 170H may be formed by performing an anisotropic etching process of removing parts of the insulating structure 113 and the plurality of active regions 118 by using the plurality of insulation capping lines 148 and the plurality of insulating spacer structures 150 covering side walls of the plurality of bit line structures 140 as etching masks and performing an isotropic etching process of further removing other parts of the plurality of active regions 118 so that the spaces limited by the plurality of active regions 118 expand.

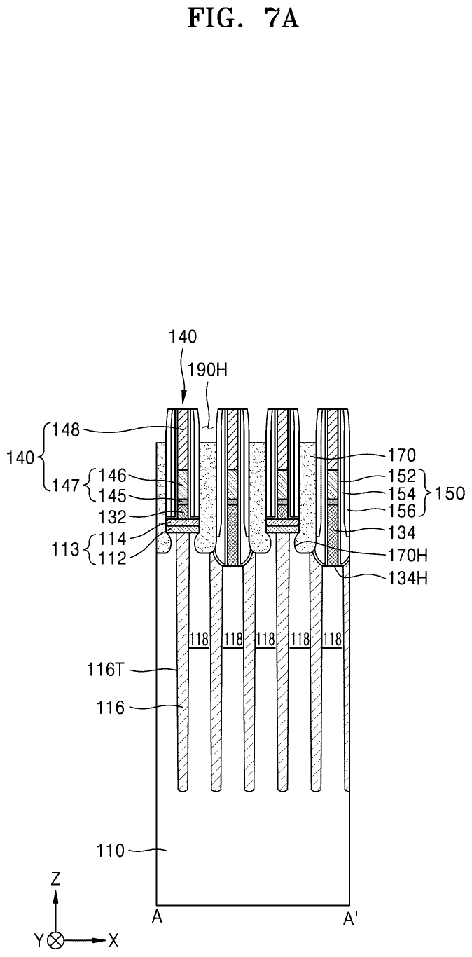

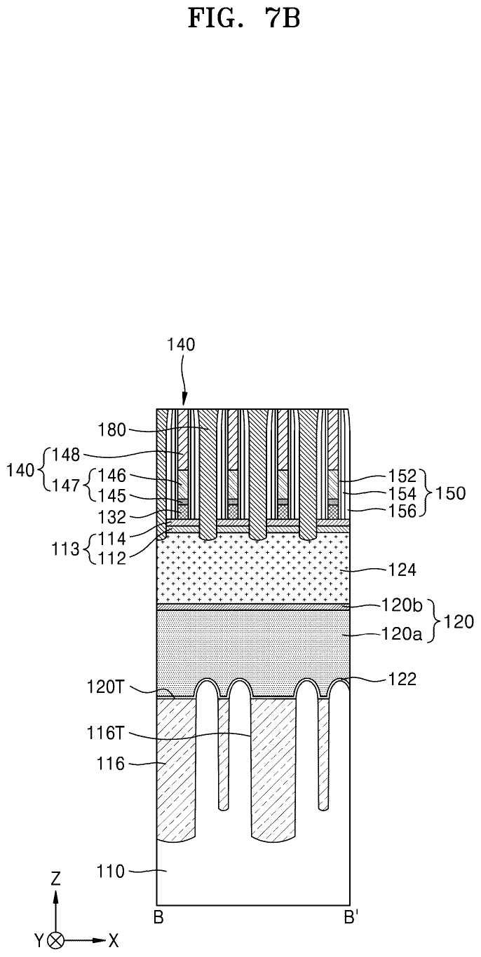

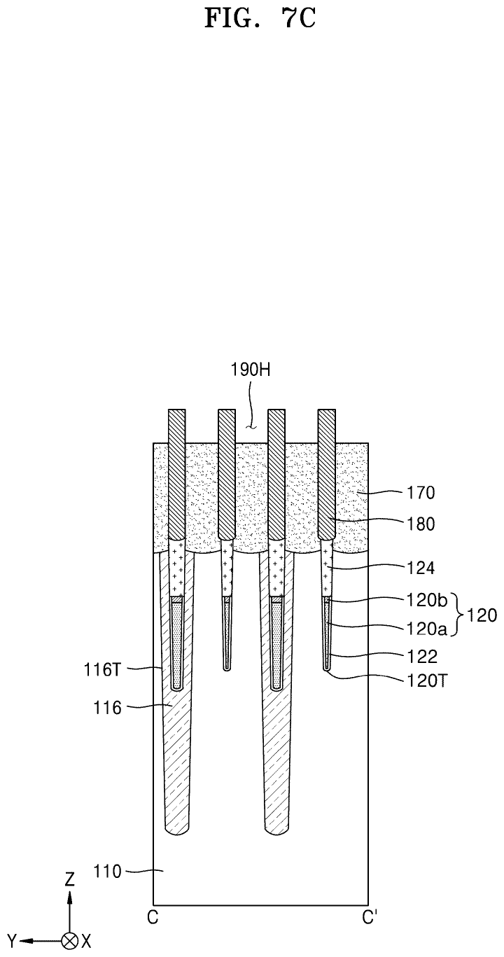

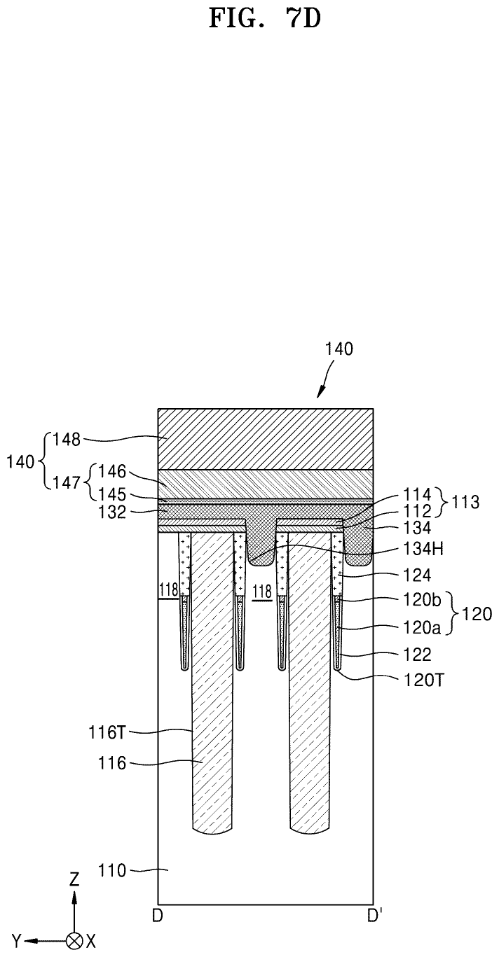

Referring to FIGS. 7A to 7D, a plurality of buried contacts 170 and a plurality of insulating fences 180 are formed in spaces among a plurality of insulating spacer structures 150 covering side walls of the plurality of bit line structures 140. Along a pair of insulating spacer structures 150 facing each other among the plurality of insulating spacer structures 150 covering side walls of the plurality of bit line structures 140, that is, in the second horizontal direction (the Y direction), the plurality of buried contacts 170 and the plurality of insulating fences 180 may be alternately arranged. For example, the plurality of buried contacts 170 may include polysilicon. For example, the plurality of insulating fences 180 may include a nitride film.

In some example embodiments, the plurality of buried contacts 170 may be arranged in a line in the first horizontal direction (the X direction) and the second horizontal direction (the Y direction). Each of the plurality of buried contacts 170 may extend from each of the plurality of active regions 118 in a direction (a Z direction) perpendicular to the substrate 110. The plurality of buried contacts 170 may constitute the plurality of buried contacts BC illustrated in FIG. 2.

The plurality of buried contacts 170 may be arranged in the spaces defined by the plurality of insulating fences 180 and the plurality of insulating spacer structures 150 covering side walls of the plurality of bit line structures 140. The plurality of buried contacts 170 may fill lower parts of the spaces among the plurality of insulating spacer structures 150 covering side walls of each of the plurality of bit line structures 140.

Top surfaces of the plurality of buried contacts 170 may be at a level lower than top surfaces of the plurality of insulation capping lines 148. Top surfaces of the plurality of insulating fences 180 and the top surfaces of the plurality of insulation capping lines 148 may be at the same level in the vertical direction (the Z direction).

A plurality of landing pad holes 190H may be limited by the plurality of insulating spacer structures 150 and the plurality of insulating fences 180. The plurality of buried contacts 170 may be exposed at bottom surfaces of the plurality of landing pad holes 190H.

In a process of forming the plurality of buried contacts 170 and/or the plurality of insulating fences 180, upper parts of the plurality of insulation capping lines 148 and the plurality of insulating spacer structures 150 included in the plurality of bit line structures 140 may be removed so that levels of top surfaces of the plurality of bit line structures 140 may be lowered.

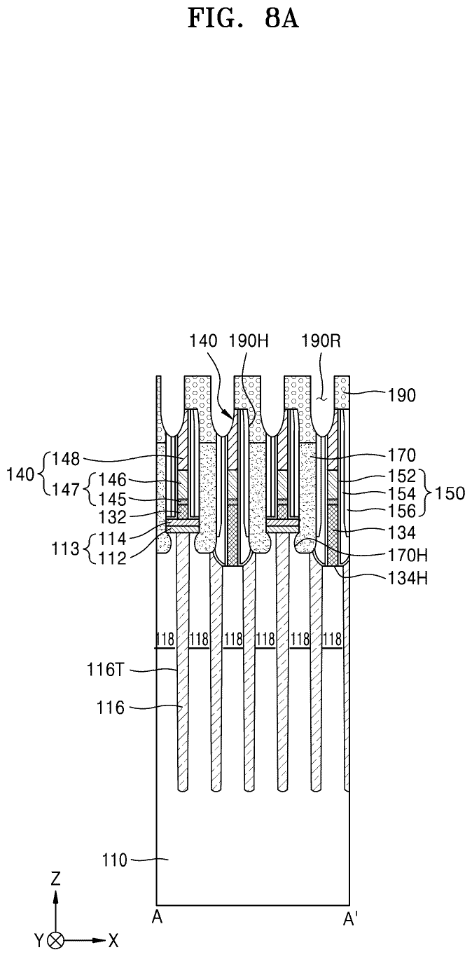

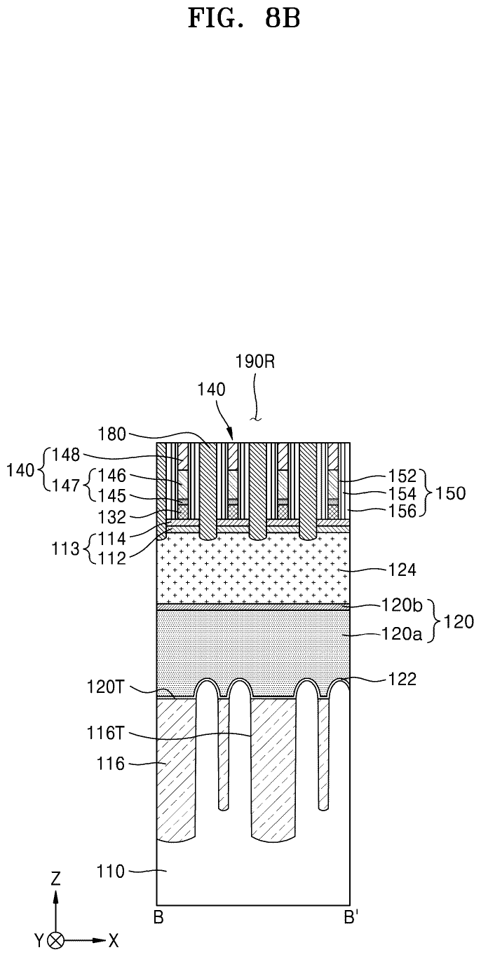

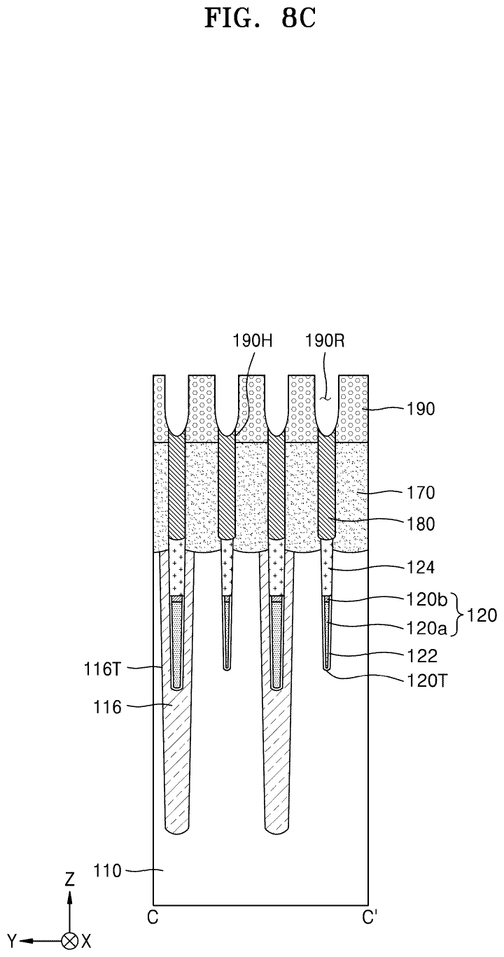

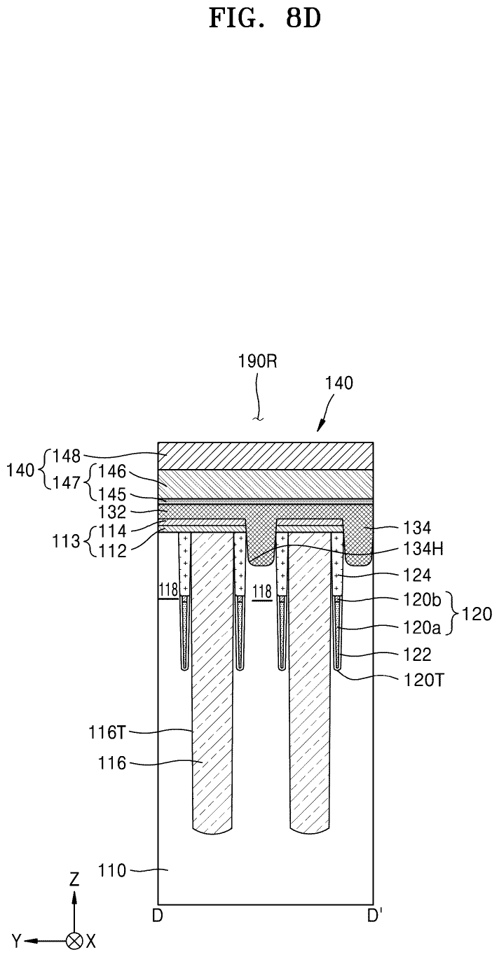

Referring to FIGS. 8A to 8D together, a landing pad material layer filling the plurality of landing pad holes 190H and covering the plurality of bit line structures 140 is formed. In some example embodiments, the landing pad material layer may include a conductive barrier layer and a conductive pad material layer on the conductive barrier layer. For example, the conductive barrier layer may include a metal, conductive metal nitride, or a combination thereof. In some example embodiments, the conductive barrier layer may have a Ti/TiN stacked structure. In some example embodiments, the conductive pad material layer may include W.

In some example embodiments, a metal silicide layer may be formed on the plurality of buried contacts 170 before forming the landing pad material layer. The metal silicide layer may be arranged between the plurality of buried contacts 170 and the landing pad material layer. The metal silicide layer may include cobalt silicide (CoSix), nickel silicide (NiSix), or manganese silicide (MnSix). However, the inventive concepts are not limited thereto.

Thereafter, part of the landing pad material layer is removed to form a plurality of landing pads 190 at least partially filling the plurality of landing pad holes 190H, extending onto the plurality of bit line structures 140, and separated by recesses 190R.

The plurality of landing pads 190 may be apart from one another with the recesses 190R therebetween. The plurality of landing pads 190 are arranged on the plurality of buried contacts 170 and may extend onto the plurality of bit line structures 140. In some example embodiments, the plurality of landing pads 190 may extend onto the plurality of bit lines 147. The plurality of landing pads 190 may be arranged on the plurality of buried contacts 170 so that the plurality of buried contacts 170 may be electrically connected to the plurality of landing pads 190, respectively. The buried contact 170 and the landing pad 190 corresponding to each other may be referred to as a contact plug. The plurality of landing pads 190 may be connected to the plurality of active regions 118 through the plurality of buried contacts 170. The plurality of landing pads 190 may constitute the plurality of landing pads LP illustrated in FIG. 2.

Each of the plurality of buried contacts 170 may be arranged between two adjacent bit line structures 140, and each of the plurality of landing pads 190 may extend from between two adjacent bit line structures 140 onto each of the plurality of bit line structures 140 with each of the plurality of buried contacts 170 therebetween.

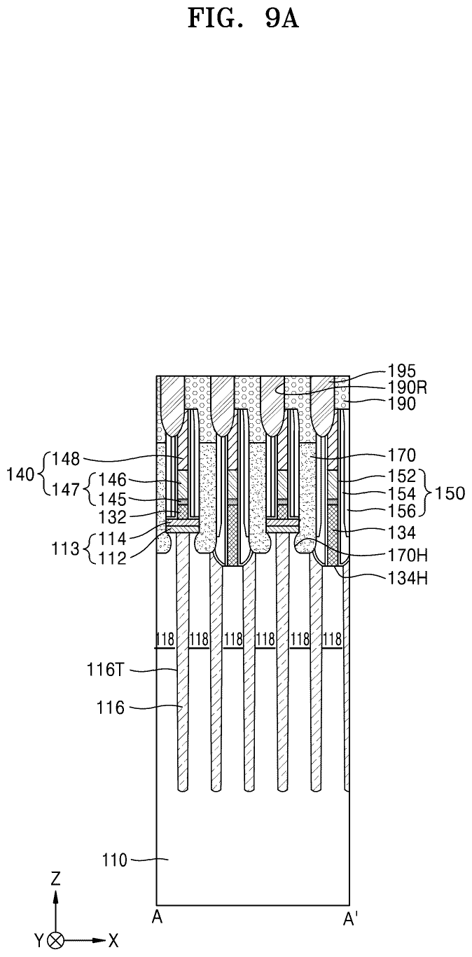

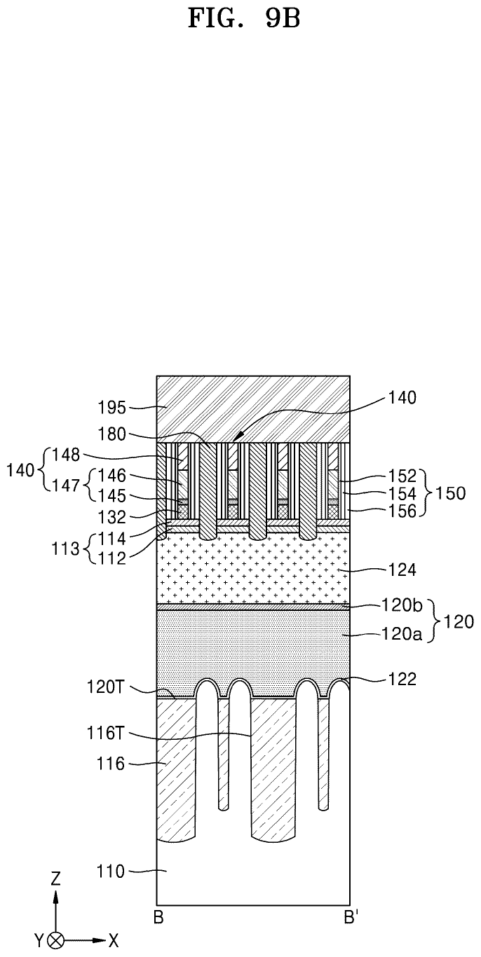

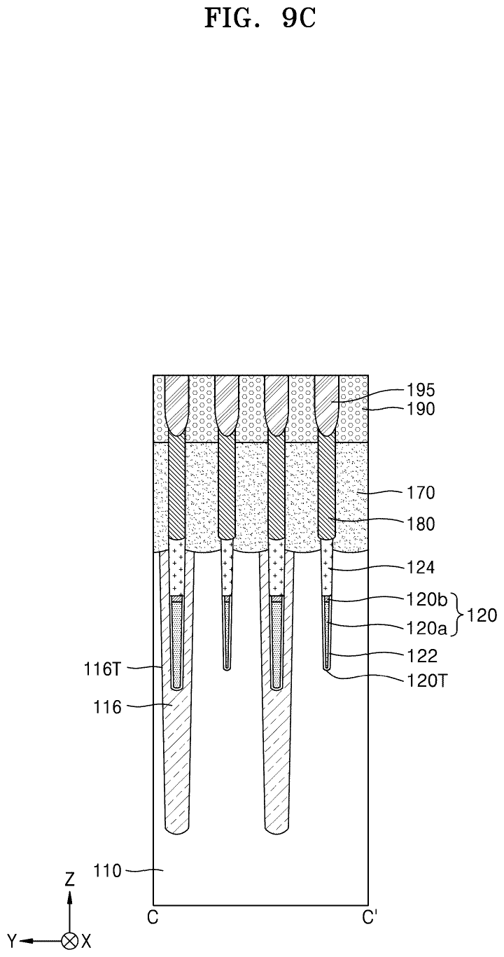

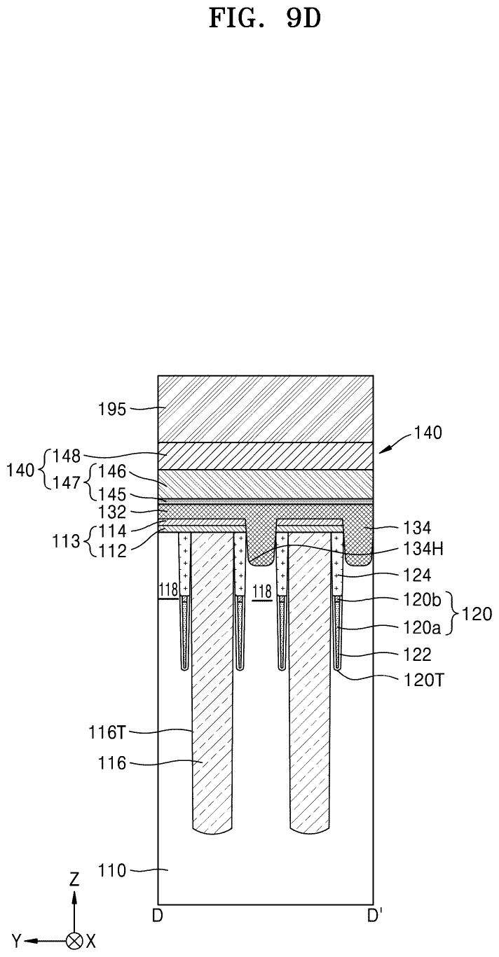

Referring to FIGS. 9A to 9D, a plurality of insulating layers 195 filling the plurality of recesses 190R may be formed. In some example embodiments, the insulating layer 195 may have a stacked structure of an oxide film and a nitride film. It is illustrated in FIGS. 9A and 9C that top surfaces of the plurality of insulating layers 195 and top surfaces of the plurality of landing pads 190 are at the same level. However, the inventive concepts are not limited thereto.

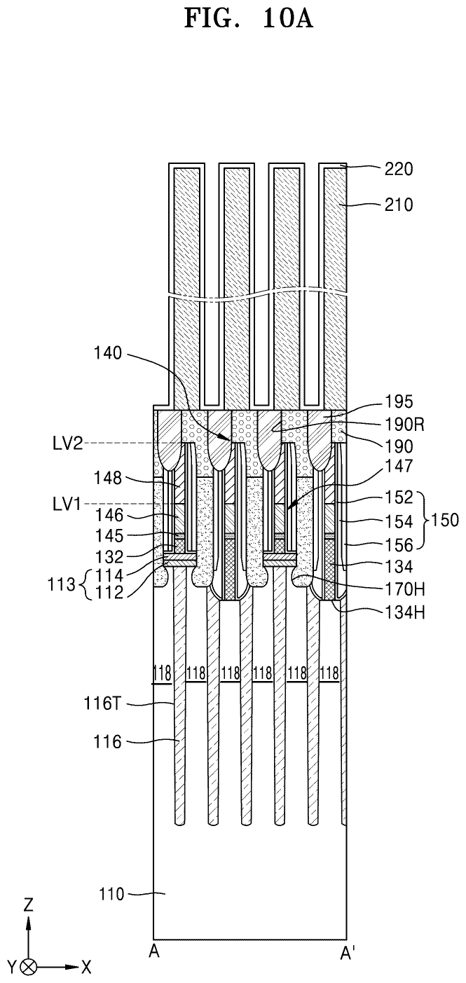

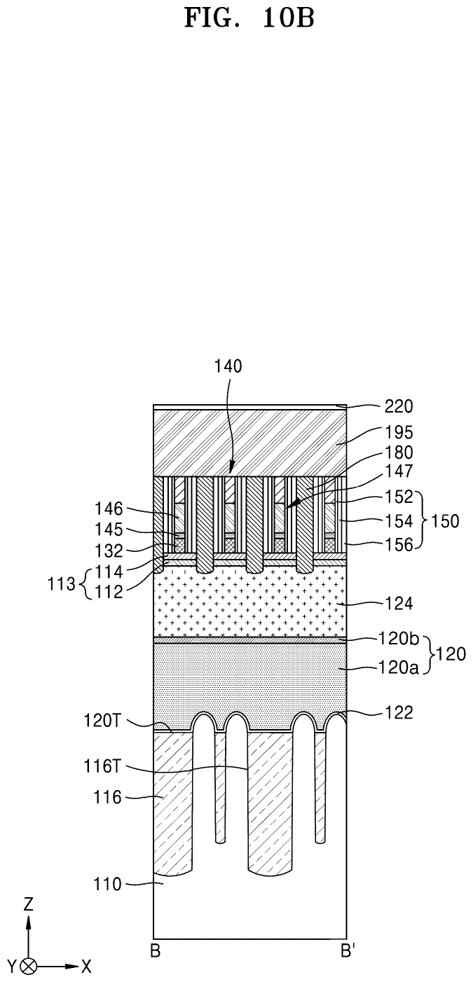

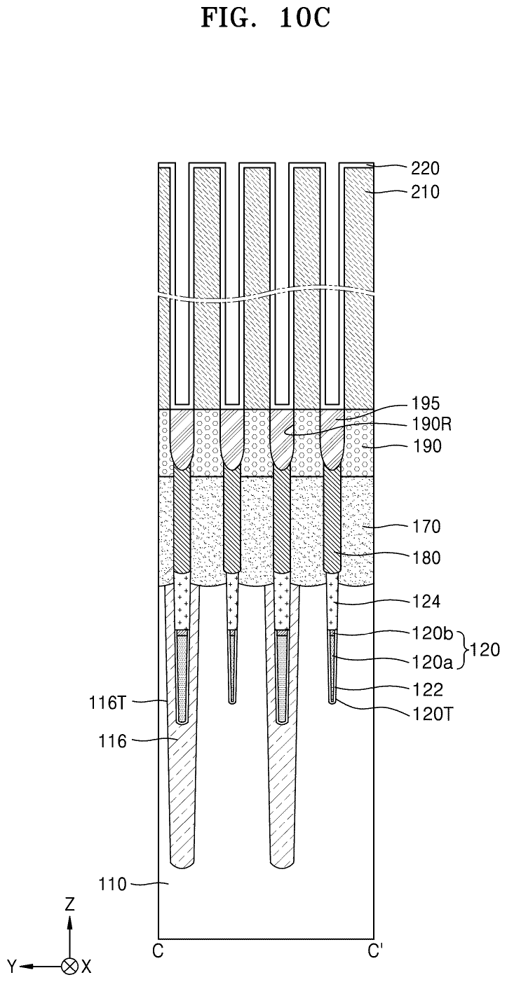

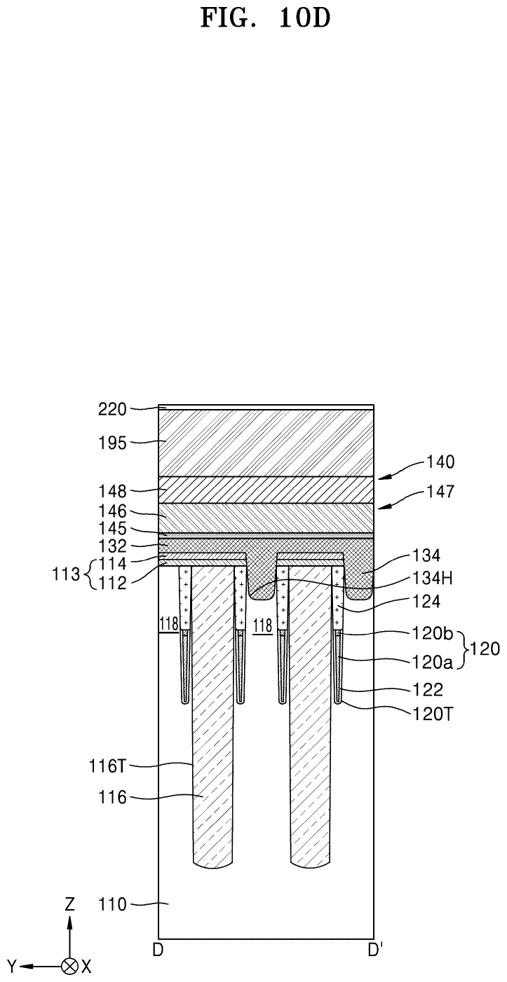

Referring to FIGS. 10A to 10D together, a plurality of lower electrodes 210 and a capacitor dielectric layer 220 are sequentially formed on the plurality of landing pads 190. The plurality of lower electrodes 210 may be electrically connected to the plurality of landing pads 190, respectively. The capacitor dielectric layer 220 may conformally cover surfaces of the plurality of lower electrodes 210. For example, the capacitor dielectric layer 220 may be formed to cover the surfaces of the plurality of lower electrodes 210 with a thickness of about or exactly 40 Å to about or exactly 70 Å. In some example embodiments, the capacitor dielectric layer 220 may be integrally formed to cover the plurality of lower electrodes 210 in a certain region, for example, the memory cell region (CR of FIG. 2). In some example embodiments, the capacitor dielectric layer 220 may be formed to cover the memory cell region CR and the peripheral region (PR of FIG. 2). The plurality of lower electrodes 210 may constitute the plurality of storage nodes SN illustrated in FIG. 2.

Each of the plurality of lower electrodes 210 may be in the form of a column of which the inside is filled to have a circular horizontal cross-section. However, the inventive concepts are not limited thereto. In some example embodiments, each of the plurality of lower electrodes 210 may be in the form of a cylinder with a closed bottom. In some example embodiments, the plurality of lower electrodes 210 may be in the form of a honeycomb arranged in zigzags in the first horizontal direction (the X direction) or the second horizontal direction (the Y direction). In some example embodiments, the plurality of lower electrodes 210 may be in a matrix arranged in a line in the first horizontal direction (the X direction) and the second horizontal direction (the Y direction). The plurality of lower electrodes 210 may include, for example, a metal such as Si, W, or Cu doped with impurities, or a conductive metal compound such as TiN. In some example embodiments, the plurality of lower electrodes 210 may include TiN. In some example embodiments, the semiconductor memory device 1 may further include at least one support pattern in contact with side walls of the plurality of lower electrodes 210. For example, the plurality of support patterns contacting the sidewalls of the plurality of lower electrodes 210 at different vertical levels may be further formed.

The capacitor dielectric layer 220 may include, for example, TaO, TaAlO, TaON, AIO, AISIO, HfO, HfSiO, ZrO, ZrSiO, TiO, TiAIO, BST((Ba,Sr)TiO), STO(SrTiO), BTO(BaTiO), PZT(Pb(Zr,Ti)O), (Pb,La)(Zr,Ti)O, Ba(Zr,Ti)O, Sr(Zr,Ti)O, and/or a combination thereof.

Referring to FIG. 11A, a metallic electrode layer 232 covering the capacitor dielectric layer 220 is formed. The metallic electrode layer 232 may include a metal or a material including a metal. For example, the metallic electrode layer 232 may include a metallic material such as W, ruthenium (Ru), platinum (Pt), iridium (Ir), vanadium (V), molybdenum (Mo), Ta, niobium(Nb), TiN, VN, MON, TaN, NbN, InN, RuO, PtO, IrO, TiO, VO, MoO, TaO, NbO, InO, SRO(SrRuO), BSRO(Ba,Sr)RuO, CRO(CaRuO), BaRuO, La(Sr,Co)O, and/or a combination thereof. In some example embodiments, the metallic electrode layer 232 may include a noble metal. For example, the metallic electrode layer 232 may include Ru, Ir, gold (Au), Pt, rhodium (Rh), palladium (Pd), silver (Ag), rhenium (Re), or osmium (Os). In some example embodiments, the metallic electrode layer 232 may include Ru. The metallic electrode layer 232 may be formed to fill all spaces among the plurality of lower electrodes 210 covered with the capacitor dielectric layer 220. For example, the metallic electrode layer 232 may be formed to have a thickness of about or exactly 100 Å to about or exactly 200 Å from the uppermost end of the capacitor dielectric layer 220.

Referring to FIG. 11B, a lower conductive semiconductor layer 234 is formed on the metallic electrode layer 232. A bottom surface of the lower conductive semiconductor layer 234 may contact a top surface of the metallic electrode layer 232. The lower conductive semiconductor layer 234 may include a group IV compound semiconductor material. In some example embodiments, the lower conductive semiconductor layer 234 may include a group IV compound semiconductor material including Ge. For example, the lower conductive semiconductor layer 234 may include silicon-germanium. When the lower conductive semiconductor layer 234 includes silicon-germanium, a concentration of Ge in the lower conductive semiconductor layer 234 may be about or exactly 30 atom % or less. For example, the concentration of Ge in the lower conductive semiconductor layer 234 may be about or exactly 15 atom % to about or exactly 30 atom %. The lower conductive semiconductor layer 234 may be formed to conformally cover a top surface of the capacitor dielectric layer 220. A thickness of the lower conductive semiconductor layer 234 may be equal to or greater than a thickness of the capacitor dielectric layer 220. The thickness of the lower conductive semiconductor layer 234 may be less than a thickness of the metallic electrode layer 232. For example, the lower conductive semiconductor layer 234 may be formed to cover the metallic electrode layer 232 with a thickness of about or exactly 50 Å to about or exactly 100 Å. The lower conductive semiconductor layer 234 may be formed under a first deposition temperature condition. The first deposition temperature may be about or exactly 440° C. to about or exactly 520° C.

Referring to FIG. 11C, an upper conductive semiconductor layer 236 is formed on the lower conductive semiconductor layer 234. The upper conductive semiconductor layer 236 may include a group IV compound semiconductor material. In some example embodiments, the upper conductive semiconductor layer 236 may include a group IV compound semiconductor material including Ge. For example, the upper conductive semiconductor layer 236 may include silicon-germanium. When both the lower conductive semiconductor layer 234 and the upper conductive semiconductor layer 236 include silicon-germanium, the upper conductive semiconductor layer 236 may be formed to have a higher Ge concentration than the lower conductive semiconductor layer 234. For example, the concentration of Ge in the upper conductive semiconductor layer 236 may be about or exactly 80 atom % to about or exactly 90 atom %. The lower conductive semiconductor layer 234 and the upper conductive semiconductor layer 236 may be respectively referred to as a low-concentration conductive semiconductor layer and a high-concentration conductive semiconductor layer.

The upper conductive semiconductor layer 236 may sufficiently thickly cover a top surface of the lower conductive semiconductor layer 234. A thickness of the upper conductive semiconductor layer 236 may be greater than each of the thickness of the metallic electrode layer 232 and the thickness of the lower conductive semiconductor layer 234. For example, the upper conductive semiconductor layer 236 may be formed to cover the lower conductive semiconductor layer 234 with a thickness of about or exactly 1,000 Å to about or exactly 4,000 Å. In some example embodiments, the thickness of the lower conductive semiconductor layer 234 may be about or exactly 5% or less of the thickness of the upper conductive semiconductor layer 236. The upper conductive semiconductor layer 236 may be formed under a second deposition temperature condition. For example, the second deposition temperature may be about or exactly 440° C. to about or exactly 480° C. The second deposition temperature may be equal to or lower than the first deposition temperature. For example, the second deposition temperature may be equal to or up to about or exactly 40° C. lower than the first deposition temperature.

The metallic electrode layer 232, the lower conductive semiconductor layer 234, and the upper conductive semiconductor layer 236 may constitute an upper electrode 230. The plurality of lower electrodes 210, the capacitor dielectric layer 220, and the upper electrode 230 may form a plurality of capacitor structures 200.

Referring to FIGS. 12A to 12D together, a cover insulating layer 260 covering the upper electrode 230 is formed. In some example embodiments, a bottom surface of the cover insulating layer 260 may directly contact a top surface of the upper conductive semiconductor layer 236. The cover insulating layer 260 may include, for example, silicon oxide. The cover insulating layer 260 may include, for example, an oxide film or an ultra-low K (ULK) film. The oxide film may include one selected from borophosphosilicate glass (BPSG), phosphosilicate glass (PSG), borosilicate glass (BSG), undoped silicon glass (USG), tetra ethyl orthosilicate (TEOS), and high density plasma (HDP). The ULK film may include, for example, one selected from SiOC and SiCOH having an ultra-low dielectric constant K of about or exactly 2.2 to about or exactly 2.4.

Part of the cover insulating layer 260 is removed to form a wiring contact hole MCH. The upper conductive semiconductor layer 236 may be exposed on a bottom surface of the wiring contact hole MCH. The wiring contact hole MCH may extend to the upper conductive semiconductor layer 236 through the cover insulating layer 260. In some example embodiments, the wiring contact hole MCH may extend into the upper conductive semiconductor layer 236. For example, the wiring contact hole MCH may extend into the upper conductive semiconductor layer 236 through the cover insulating layer 260, but may not extend to the lower conductive semiconductor layer 234. A vertical level of the bottom surface of the wiring contact hole MCH may be at a vertical level lower than the uppermost end of the upper conductive semiconductor layer 236 and higher than the uppermost end of the lower conductive semiconductor layer 234.

A wiring contact plug 310 filling the wiring contact hole MCH is formed. The wiring contact plug 310 may contact the upper conductive semiconductor layer 236 but may not contact the lower conductive semiconductor layer 234. In some example embodiments, the wiring contact plug 310 may extend into the upper conductive semiconductor layer 236. For example, the wiring contact plug 310 may extend into the upper conductive semiconductor layer 236 through the cover insulating layer 260 but may not extend to the lower conductive semiconductor layer 234. A vertical level of a bottom surface of the wiring contact plug 310 may be at a vertical level lower than the uppermost end of the upper conductive semiconductor layer 236 and higher than the uppermost end of the lower conductive semiconductor layer 234. Each of the wiring contact hole MCH and the wiring contact plug 310 may have a tapered shape extending from a lower side to an upper side in the vertical direction (the Z direction) with an increasing horizontal width.

The wiring contact plug 310 may include a wiring contact barrier layer 312 and a wiring contact filling layer 314. The wiring contact barrier layer 312 may be formed to conformally cover surfaces of the cover insulating layer 260 and the upper conductive semiconductor layer 236 exposed at an internal surface, that is, an internal wall and the bottom surface of the wiring contact hole MCH, and the wiring contact filling layer 314 may be formed to cover the wiring contact barrier layer 312 and to fill the wiring contact hole MCH. For example, the wiring contact barrier layer 312 may include Ti, Ta, TiN, or TaN. For example, the wiring contact filling layer 314 may include a metal such as W.

The semiconductor memory device 1 may be formed by forming a wiring line 320 connected to the wiring contact plug 310 on the cover insulating layer 260 in which the wiring contact plug 310 is formed. The plurality of wiring lines 320 may include, for example, a metal such as Al, Cu, or W.

A semiconductor memory device 1 includes a substrate 110 crossing a plurality of active regions 118, a plurality of gate dielectric layers 122, a plurality of word lines 120, and a plurality of buried insulating layers 124 sequentially formed in a plurality of word line trenches 120T crossing the plurality of active regions 118 in the substrate 110, an insulating structure 113 covering a device isolation layer 116, the plurality of active regions 118, and the plurality of buried insulating layers 124, a plurality of bit line structures 140 on the insulating structure 113, a plurality of insulating spacer structures 150 each covering both sidewalls of each of the plurality of bit line structures 140, a plurality of buried contacts 170 filling lower portions of spaces defined by the plurality of insulating fences 180 and the plurality of insulating spacer structures 150 and connected to the plurality of active regions 118 and a plurality of landing pads 190 filling upper portions of the spaces defined by the plurality of insulating fences 180 and the plurality of insulating spacer structures 150 and extending to upper portions of the plurality of bit line structures 140, a plurality of capacitor structures 200 including a plurality of lower electrodes 210 connected to the plurality of landing pads 190, a capacitor dielectric layer 220, and an upper electrode 230, a wiring contact plug 310 connected to the upper electrode 230, and a wiring line 320 connected to the wiring contact plug 310.

The upper electrode 230 may form a stacked structure including a metallic electrode layer 232, a lower conductive semiconductor layer 234, and an upper conductive semiconductor layer 236. The metallic electrode layer 232 may be formed to fill all spaces among the plurality of lower electrodes 210 covered with the capacitor dielectric layer 220. The metallic electrode layer 232 may include a noble metal. In some example embodiments, the metallic electrode layer 232 may include Ru. The lower conductive semiconductor layer 234 may include a group IV compound semiconductor material. In some example embodiments, the lower conductive semiconductor layer 234 may include a group IV compound semiconductor material including Ge. The lower conductive semiconductor layer 234 may be formed to conformally cover a top surface of the capacitor dielectric layer 220. The upper conductive semiconductor layer 236 may include a group IV compound semiconductor material. In some example embodiments, the upper conductive semiconductor layer 236 may include a group IV compound semiconductor material including Ge. When both the lower conductive semiconductor layer 234 and the upper conductive semiconductor layer 236 include silicon-germanium, the upper conductive semiconductor layer 236 may be formed to have a higher Ge concentration than the lower conductive semiconductor layer 234. For example, the concentration of Ge in the lower conductive semiconductor layer 234 may be about or exactly 15 atom % to about or exactly 30 atom %, and the concentration of Ge in the upper conductive semiconductor layer 236 may be about or exactly 80 atom % to about or exactly 90 atom %. The lower conductive semiconductor layer 234 may be formed under the first deposition temperature condition, and the upper conductive semiconductor layer 236 may be formed under the second deposition temperature condition. The second deposition temperature may be equal to or lower than the first deposition temperature. For example, the second deposition temperature may be equal to or up to about 40° C. (e.g., a different of about or exactly 0° C. to about or exactly 40° C.) lower than the first deposition temperature.

The upper conductive semiconductor layer 236 with a relatively high Ge concentration has a higher deposition rate and may be formed under a lower temperature condition compared to the lower conductive semiconductor layer 234 with a relatively low Ge concentration.

The capacitor dielectric layer 220 may have a first thickness T1, the metallic electrode layer 232 may have a second thickness T2 from the uppermost end of the capacitor dielectric layer 220, the lower conductive semiconductor layer 234 may have a third thickness T3, and the upper conductive semiconductor layer 236 may have a fourth thickness T4. The second thickness T2 may be greater than the first thickness T1. The third thickness T3 may be equal to or greater than the first thickness T1. The third thickness T3 may be less than the second thickness T2. The fourth thickness T4 may be greater than each of the first thickness T1, the second thickness T2, and the third thickness T3. For example, the first thickness T1 may be about or exactly 40 Å to about or exactly 70 Å. For example, the second thickness T2 may be about or exactly 100 Å to about or exactly 200 Å. For example, the third thickness T3 may be about or exactly 50 Å to about or exactly 100 Å. The fourth thickness T4 may be about or exactly 1,000 Å to about or exactly 4,000 Å. The third thickness T3 may be about or exactly 5% or less of the fourth thickness T4.

On the lower electrode 210, the sum of the first height H1 from the bottom surface of the upper conductive semiconductor layer 236 to the lowermost end of the wiring contact plug 310 and the second height H2 from the lowermost end of the wiring contact plug 310 to the top surface of the upper conductive semiconductor layer 236 may be the fourth thickness T4. The second height H2 may be equal to or less than the first height H1. That is, the second height H2 may be half the fourth thickness T4 or less. The second height H2 may be a length in which the wiring contact plug 310 extends in the upper conductive semiconductor layer 236 in the vertical direction (the Z direction). The wiring contact plug 310 may extend from the top surface of the upper conductive semiconductor layer 236 into the upper conductive semiconductor layer 236 by a second height H2 that is half the fourth thickness T4 or less, which is the total thickness of the upper conductive semiconductor layer 236.

In the semiconductor memory device 1 according to the inventive concepts, because the lower conductive semiconductor layer 234 covering the metallic electrode layer 232 has a relatively lower Ge concentration than the upper conductive semiconductor layer 236, formation of a metal compound by part of the metal electrode layer 232 in a subsequent heat treatment process may be minimized or reduced.

In addition, because the lower conductive semiconductor layer 234 is formed to be thinner than the upper conductive semiconductor layer 236 in the semiconductor memory device 1 according to the inventive concepts, a thermal budget may be reduced in the process of forming the lower conductive semiconductor layer 234 and the upper conductive semiconductor layer 236, thereby minimizing or reducing the formation of the metal compound by part of the metal-based electrode layer 232.

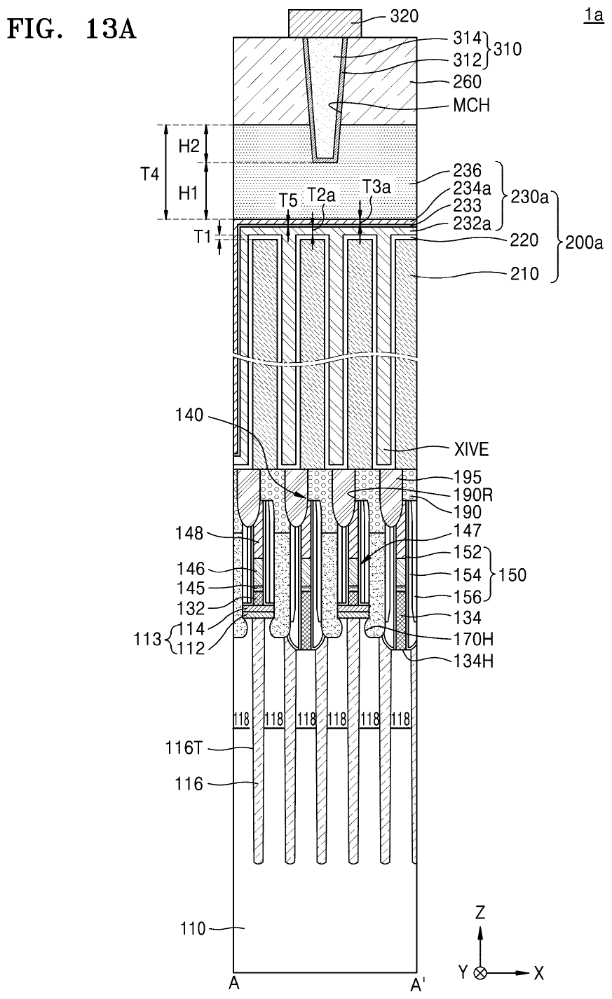

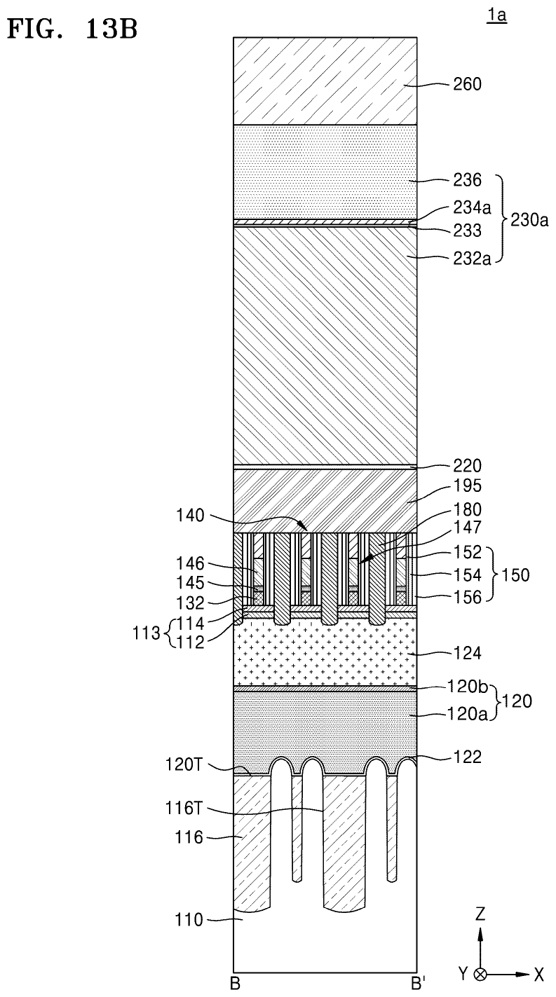

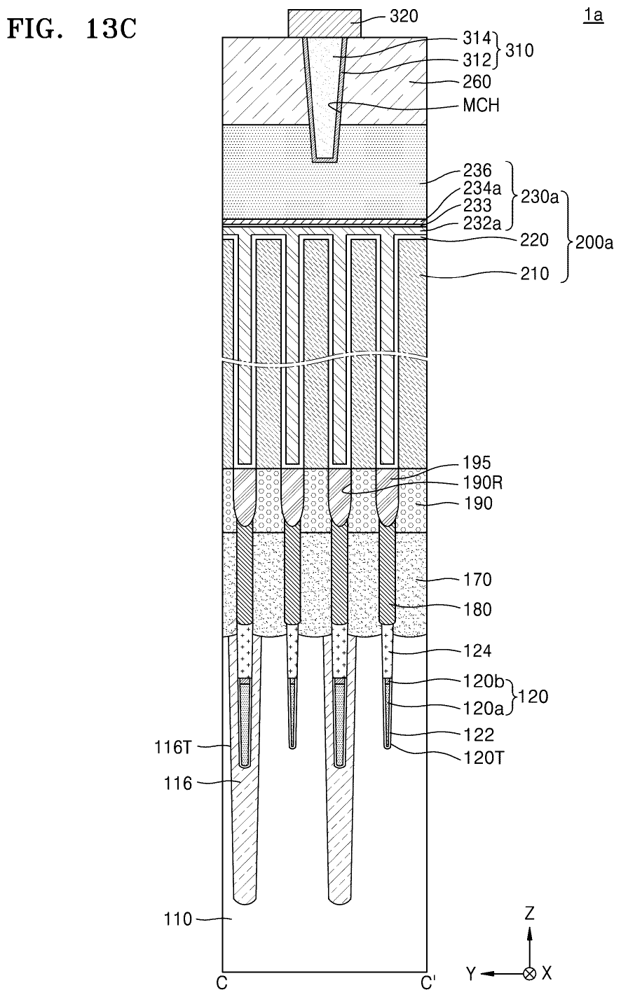

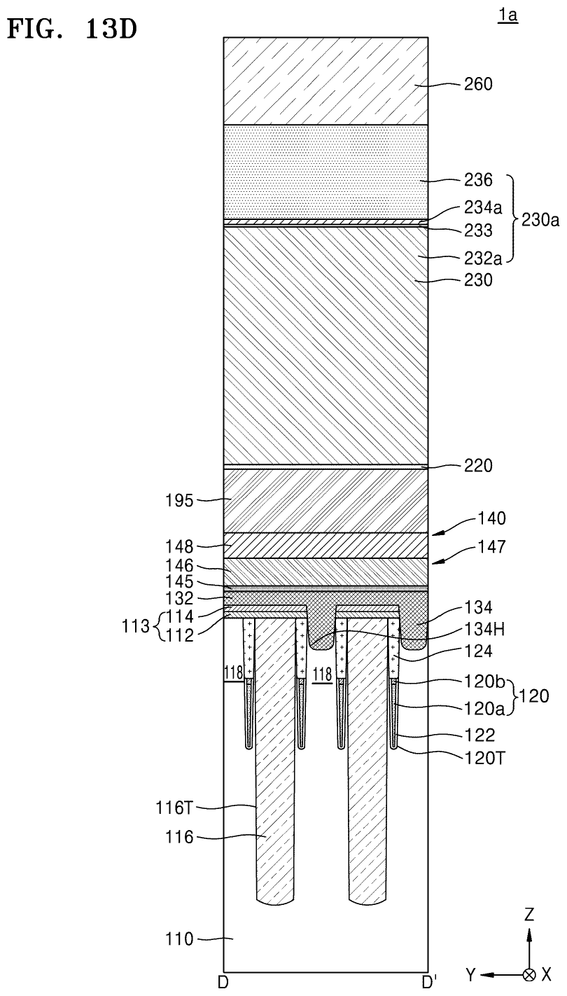

FIGS. 13A to 13D are cross-sectional views illustrating a semiconductor memory device according to some example embodiments.

Referring to FIGS. 13A to 13D, a semiconductor memory device 1a includes a substrate 110 crossing a plurality of active regions 118, a plurality of gate dielectric layers 122, a plurality of word lines 120, and a plurality of buried insulating layers 124 sequentially formed in a plurality of word line trenches 120T crossing the plurality of active regions 118 in the substrate 110, an insulating structure 113 covering a device isolation layer 116, the plurality of active regions 118, and the plurality of buried insulating layers 124, a plurality of bit line structures 140 on the insulating structure 113, a plurality of insulating spacer structures 150 each covering both sidewalls of each of the plurality of bit line structures 140, a plurality of buried contacts 170 filling lower portions of spaces defined by the plurality of insulating fences 180 and the plurality of insulating spacer structures 150 and connected to the plurality of active regions 118 and a plurality of landing pads 190 filling upper portions of the spaces defined by the plurality of insulating fences 180 and the plurality of insulating spacer structures 150 and extending to upper portions of the plurality of bit line structures 140, a plurality of capacitor structures 200a including a plurality of lower electrodes 210 connected to the plurality of landing pads 190, a capacitor dielectric layer 220, and an upper electrode 230a, a wiring contact plug 310 connected to the upper electrode 230a, and a wiring line 320 connected to the wiring contact plug 310.

The upper electrode 230a may form a stacked structure including a metallic electrode layer 232a, a metal compound layer 233, a lower conductive semiconductor layer 234a, and an upper conductive semiconductor layer 236. The metallic electrode layer 232a may be formed to fill all spaces among the plurality of lower electrodes 210 covered with the capacitor dielectric layer 220. The metallic electrode layer 232a may include a noble metal. In some example embodiments, the metallic electrode layer 232a may include Ru. The lower conductive semiconductor layer 234a may include a group IV compound semiconductor material. In some example embodiments, the lower conductive semiconductor layer 234a may include a group IV compound semiconductor material including Ge. The metal compound layer 233 may be between the metallic electrode layer 232a and the lower conductive semiconductor layer 234a. The metal compound layer 233 may include a compound of a metal element included in the metallic electrode layer 232a and a semiconductor element included in the lower conductive semiconductor layer 234a. For example, the metal compound layer 233 may include metal germanide or metal silicide. For example, when the metallic electrode layer 232a includes Ru as a metal element and the lower conductive semiconductor layer 234a includes silicon-germanium, the metal compound layer 233 may include ruthenium germanide or ruthenium silicide. The metal compound layer 233 may be between a top surface of the metallic electrode layer 232a and a bottom surface of the lower conductive semiconductor layer 234a. The upper conductive semiconductor layer 236 may include a group IV compound semiconductor material. In some example embodiments, the upper conductive semiconductor layer 236 may include a group IV compound semiconductor material including Gc. When both the lower conductive semiconductor layer 234a and the upper conductive semiconductor layer 236 include silicon-germanium, the upper conductive semiconductor layer 236 may be formed to have a higher Ge concentration than the lower conductive semiconductor layer 234a. For example, the concentration of Ge in the lower conductive semiconductor layer 234a may be about or exactly 15 atom % to about or exactly 30 atom %, and the concentration of Ge in the upper conductive semiconductor layer 236 may be about or exactly 80 atom % to about or exactly 90 atom %. The lower conductive semiconductor layer 234a may be formed under the first deposition temperature condition, and the upper conductive semiconductor layer 236 may be formed under the second deposition temperature condition. The second deposition temperature may be equal to or lower than the first deposition temperature. For example, the second deposition temperature may be equal to or up to about 40° C. (e.g., a different of about or exactly 0° C. to about or exactly 40° C.) lower than the first deposition temperature.

The capacitor dielectric layer 220 may have a first thickness T1, the metallic electrode layer 232a may have a second thickness T2a from the uppermost end of the capacitor dielectric layer 220, the lower conductive semiconductor layer 234a may have a third thickness T3a, the upper conductive semiconductor layer 236 may have a fourth thickness T4, and the metal compound layer 233 may have a fifth thickness T5. The second thickness T2a may be greater than the first thickness T1. The third thickness T3a may be equal to or greater than the first thickness T1. The third thickness T3a may be less than the second thickness T2a. The fourth thickness T4 may be greater than each of the first thickness T1, the second thickness T2a, and the third thickness T3a. The fifth thickness T5 may be less than each of the second thickness T2a, the third thickness T3a, and the fourth thickness T4. For example, the first thickness T1 may be about or exactly 40 Å to about or exactly 70 Å. For example, the second thickness T2a may be about or exactly 100 Å to about or exactly 200 Å. For example, the third thickness T3a may be about or exactly 50 Å to about or exactly 100 Å. The fourth thickness T4 may be about or exactly 1,000 Å to about or exactly 4,000 Å. The third thickness T3a may be about or exactly 5% or less of the fourth thickness T4. The fifth thickness T5 may be about or exactly 10 Å to about or exactly 50 Å. In some example embodiments, the fifth thickness T5 may be equal to half the second thickness T2a or less.

In the semiconductor memory device 1a according to the inventive concepts, because the lower conductive semiconductor layer 234a covering the metallic electrode layer 232a has a relatively lower Ge concentration than the upper conductive semiconductor layer 236, although part of the metallic electrode layer 232a is combined with part of the lower conductive semiconductor layer 234a to form the metal compound layer 233 in a subsequent heat treatment process, the fifth thickness T5 that is the thickness of the formed metal compound layer 233 may be minimized or reduced.

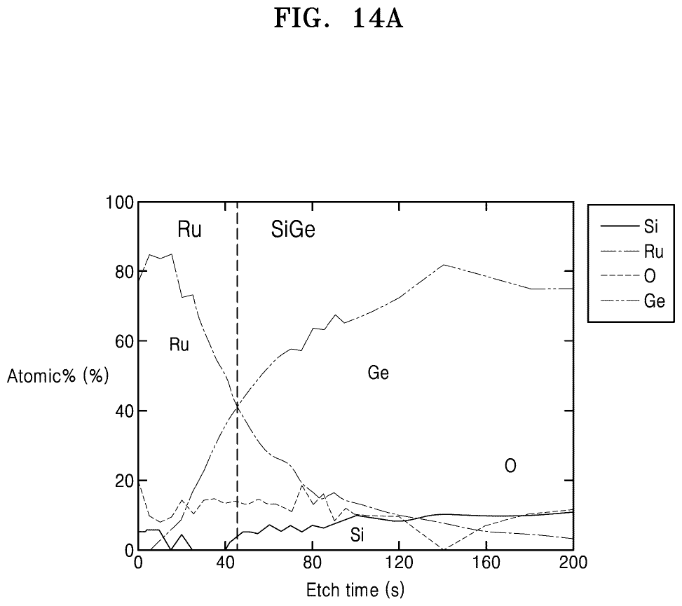

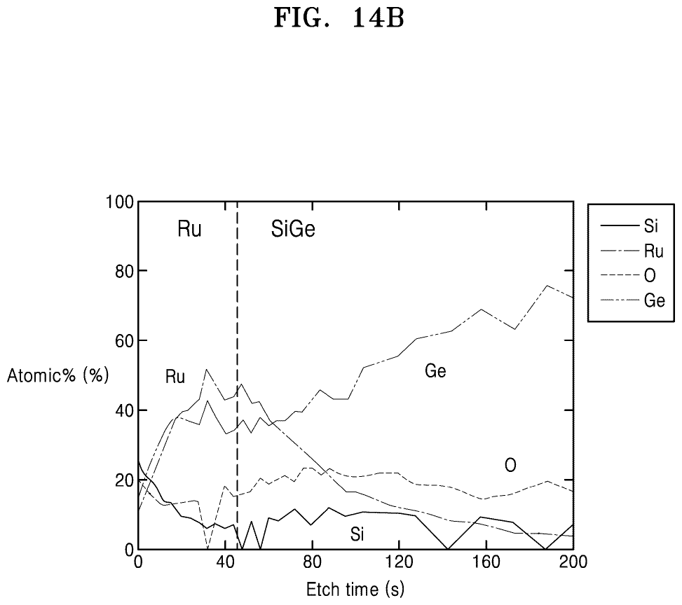

FIGS. 14A and 14B illustrate depth profiles of an example material forming an upper electrode of a semiconductor memory device according to some example embodiments.

FIGS. 14A and 14B illustrate depth profiles before heat treatment (FIG. 14A) and after heat treatment (FIG. 14B) when a conductive semiconductor layer including silicon-germanium is deposited on a metallic electrode layer including Ru. For example, heat treatment may be performed at about or exactly 600° C. When the concentration of Ge in the conductive semiconductor layer is about or exactly 80 atom %, it may be noted that Ge is mainly diffused into the metallic electrode layer when thermal treatment is performed.

Ge diffused into the metallic electrode layer may form the metal compound layer 233 illustrated in FIGS. 13A to 13D. Referring to FIGS. 12A to 12D, 13A to 13D, and 14A and 14B together, in the semiconductor memory devices 1 and 1a according to the inventive concepts, because the metallic electrode layers 232 and 232a are covered with the lower conductive semiconductor layers 234 and 234a having a relatively low Ge concentration, the Ge element included in the lower conductive semiconductor layers 234 and 234a is less diffused to the metallic electrode layers 232 and 232a so that the metal compound layer 233 may not be formed as illustrated in FIGS. 12A to 12D, or the metal compound layer 233 may be formed as illustrated in FIGS. 13A to 13D with a minimized or reduced thickness.

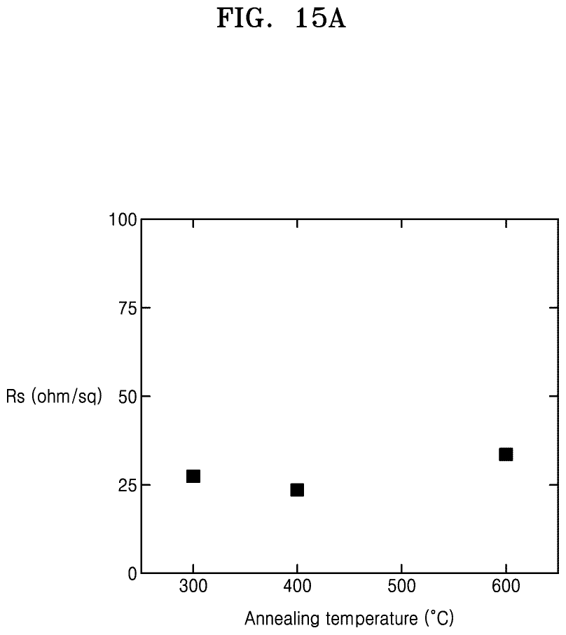

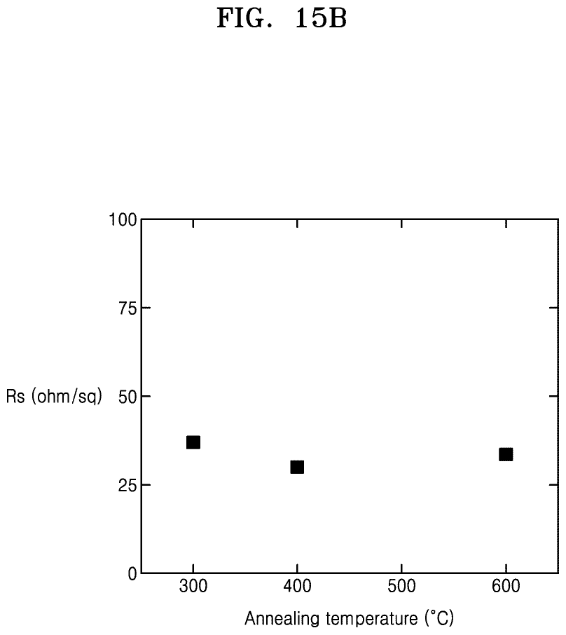

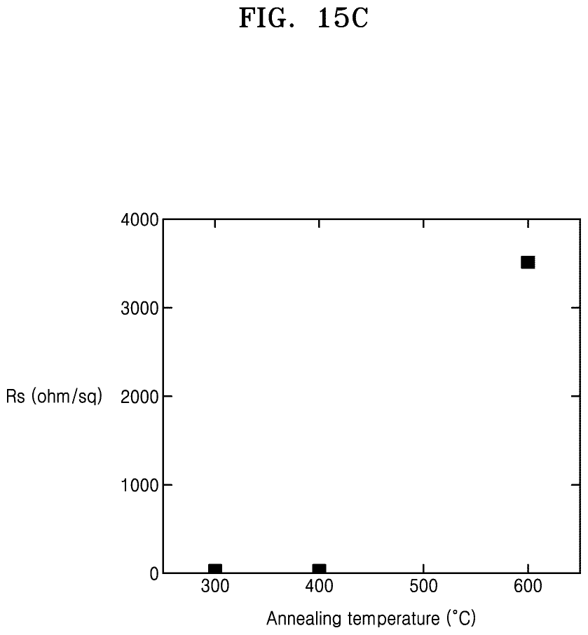

FIGS. 15A to 15C illustrate changes in sheet resistance of an example material forming an upper electrode of a semiconductor memory device according to some example embodiments.

FIGS. 15A to 15C illustrate changes in sheet resistance according to heat treatment temperature of a conductive semiconductor layer including silicon-germanium. FIGS. 15A, 15B, and 15C illustrate changes in sheet resistance according to heat treatment temperatures of conductive semiconductor layers including silicon-germanium with Ge concentrations of about or exactly 15 atom %, about or exactly 30 atom %, and about or exactly 80 atom %, respectively. The conductive semiconductor layer including silicon-germanium with the Ge concentration of about or exactly 15 atom % or about or exactly 30 atom % shows little change in sheet resistance according to heat treatment temperature. However, it may be noted that the sheet resistance of the conductive semiconductor layer including silicon-germanium with the Ge concentration of about or exactly 80 atom % increases rapidly when the heat treatment temperature is high, for example, about or exactly 600° C. As illustrated in FIG. 14B, when Ge is diffused into the metallic electrode layer, because the metal compound layer is formed, sheet resistance increases.

Referring to FIGS. 12A to 12D, 13A to 13D, and 15A and 15C together, in the semiconductor memory devices 1 and 1a according to the inventive concepts, because not the upper conductive semiconductor layer 236 having a relatively high Ge concentration but the lower conductive semiconductor layers 234 and 234a having a relatively low Ge concentration cover the metallic electrode layers 232 and 232a, the Ge element included in the lower conductive semiconductor layers 234 and 234a is diffused less to the metallic electrode layers 232 and 232a so that the metal compound layer 233 may not be formed as illustrated in FIGS. 12A to 12D or may be formed with a minimized or reduced thickness as illustrated in FIGS. 13A to 13D. Therefore, in the semiconductor memory devices 1 and 1a according to the inventive concepts, sheet resistance of the upper electrodes 230 and 230a is reduced so that reliability of the capacitor structures 200 and 200a may be secured or improved.

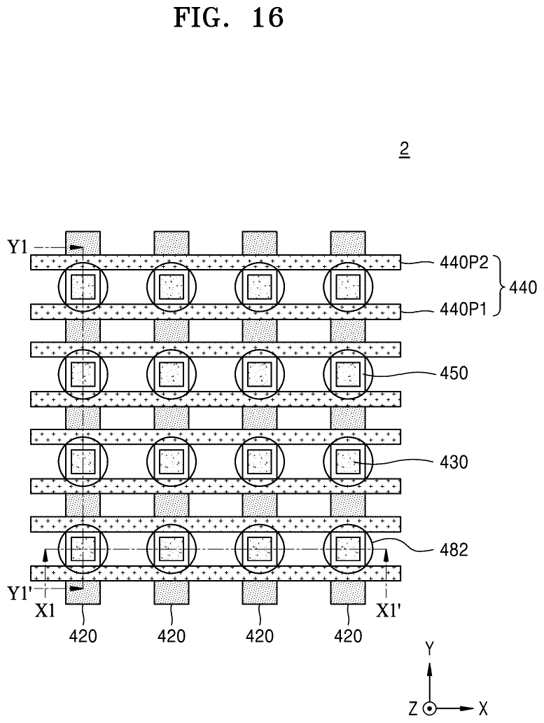

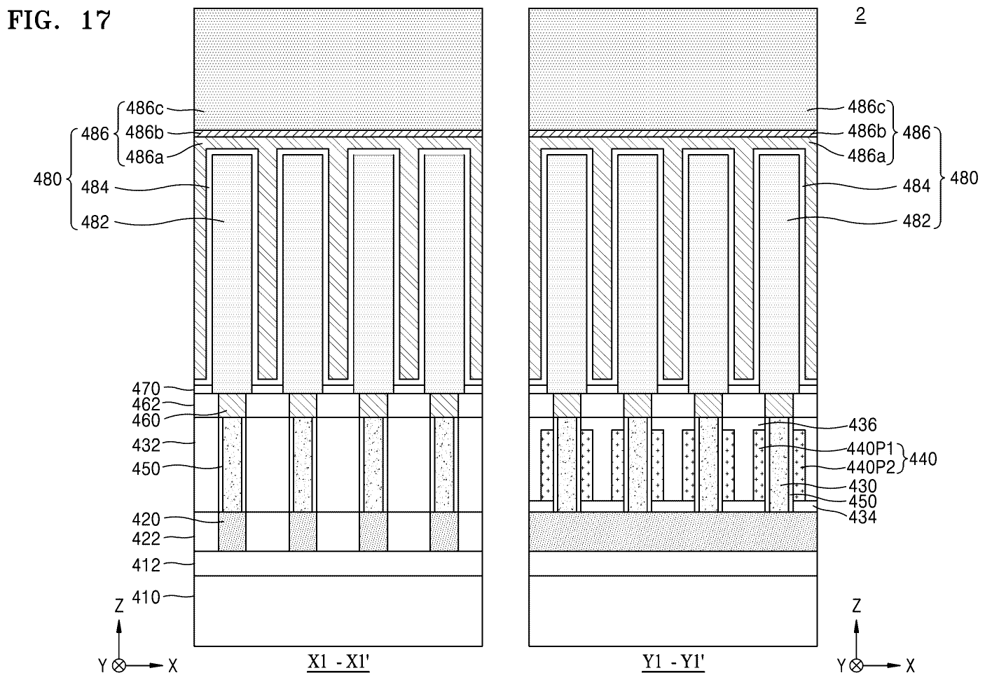

FIG. 16 is a layout diagram illustrating a semiconductor memory device 2 according to some example embodiments, and FIG. 17 is a cross-sectional view taken along line X1-X1′ and line Y1-Y1′ of FIG. 16.

Referring to FIGS. 16 and 17, the semiconductor memory device 2 may include a substrate 410, a plurality of first conductive lines 420, a channel layer 430, a gate electrode 440, a gate insulating layer 450, and a capacitor structure 480. The semiconductor memory device 2 may include a memory device including a vertical channel transistor (VCT). The VCT may refer to a structure in which a channel length of the channel layer 430 extends from the substrate 410 in the vertical direction.

A lower insulating layer 412 may be arranged on the substrate 410, and the plurality of first conductive lines 420 may be apart from one another in the first horizontal direction (the X direction) and may extend in the second horizontal direction (the Y direction) on the lower insulating layer 412. A plurality of first insulating patterns 422 may be arranged on the lower insulating layer 412 to fill spaces among the plurality of first conductive lines 420. The plurality of first insulating patterns 422 may extend in the second horizontal direction (the Y direction), and top surfaces of the plurality of first insulating patterns 422 may be at the same level as top surfaces of the plurality of first conductive lines 420. The plurality of first conductive lines 420 may function as bit lines of the semiconductor memory device 2.

In some example embodiments, the plurality of first conductive lines 420 may include doped polysilicon, a metal, conductive metal nitride, conductive metal silicide, conductive metal oxide, or a combination thereof. For example, the plurality of first conductive lines 420 may include doped polysilicon, Al, Cu, Ti, Ta, Ru, W, Mo, Pt, Ni, Co, TIN, TaN, WN, NbN, TiAl, TIAIN, TiSi, TiSiN, TaSi, TaSIN, RuTiN, NiSi, CoSi, IrOₓ, RuOₓ, or a combination thereof. However, the inventive concepts are not limited thereto. The plurality of first conductive lines 420 may include a single layer or a multilayer of the above-described materials. In some example embodiments, the plurality of first conductive lines 420 may include a two-dimensional (2D) semiconductor material, for example, graphene, carbon nanotube, or a combination thereof.

The channel layer 430 may be arranged on the plurality of first conductive lines 420 in a matrix to be apart from one another in the first horizontal direction (the X direction) and the second horizontal direction (the Y direction). The channel layer 430 may have a first width in the first horizontal direction (the X direction) and a first height in a third direction (the Z direction), and the first height may be greater than the first width. For example, the first height may be about or exactly 2 to about or exactly 10 times the first width. However, the inventive concepts are not limited thereto. A bottom of the channel layer 430 may function as a first source/drain region (not shown), an upper portion of the channel layer 430 may function as a second source/drain region (not shown), and part of the channel layer 430 between the first and second source/drain regions may function as a channel region (not shown).

In some example embodiments, the channel layer 430 may include an oxide semiconductor, and for example, the oxide semiconductor may include InₓGa_{y}Zn₂O, InₓGa_{y}Si_{z}O, InₓSn_{y}Zn_{y}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O or a combination thereof. The channel layer 430 may include a single layer or a multilayer of the oxide semiconductor. In some example embodiments, the channel layer 430 may have bandgap energy greater than that of silicon. For example, the channel layer 430 may have bandgap energy of about or exactly 1.5 eV to about or exactly 5.6 eV. For example, the channel layer 430 may have optimal channel performance when the channel layer 430 has bandgap energy of about or exactly 2.0 eV to about or exactly 4.0 eV. For example, the channel layer 430 may be polycrystalline or amorphous. However, the inventive concepts are not limited thereto. In some example embodiments, the channel layer 430 may include a 2D semiconductor material, for example, graphene, carbon nanotube, or a combination thereof.

The gate electrode 440 may extend in the first horizontal direction (the X direction) on both sidewalls of the channel layer 430. The gate electrode 440 may include a first sub-gate electrode 440P1 facing a first sidewall of the channel layer 430 and a second sub-gate electrode 440P2 facing a second sidewall opposite the first sidewall of the channel layer 430. As one channel layer 430 is arranged between the first sub-gate electrode 440P1 and the second sub-gate electrode 440P2, the semiconductor memory device 2 may have a dual gate transistor structure. However, the inventive concepts are not limited thereto, and a single gate transistor structure may be implemented by omitting the second sub-gate electrode 440P2 and forming only the first sub-gate electrode 440P1 facing the first sidewall of the channel layer 430.

The gate electrode 440 may include doped polysilicon, a metal, conductive metal nitride, conductive metal silicide, conductive metal oxide, or a combination thereof. For example, the gate electrode 440 may include doped polysilicon, Al, Cu, Ti, Ta, Ru, W, Mo, Pt, Ni, Co, TiN, TaN, WN, NON, TiAl, TiAIN, TiSi, TiSiN, TaSi, TaSiN, RuTiN, NiSi, CoSi, IrOₓ, RuOₓ, or a combination thereof. However, the inventive concepts are not limited thereto.

The gate insulating layer 450 may surround sidewalls of the channel layer 430, and may be between the channel layer 430 and the gate electrode 440. For example, as illustrated in FIG. 16, the sidewalls of the channel layer 430 may be entirely surrounded by the gate insulating layer 450, and sidewalls of the gate electrode 440 may partially contact the gate insulating layer 450. In some example embodiments, the gate insulating layer 450 may extend in a direction, that is, the first horizontal direction (the X direction) in which the gate electrode 440 extends, and only two of the sidewalls of the channel layer 430 facing the gate electrode 440 may contact the gate insulating layer 450.

In some example embodiments, the gate insulating layer 450 may include a silicon oxide film, a silicon oxynitride film, a high-k dielectric film having a higher dielectric constant than the silicon oxide film, or a combination thereof. The high dielectric layer may include metal oxide or metal oxynitride. For example, the high-k dielectric film that may be used as the gate insulating layer 450 may include HfO₂, HfSiO, HfSiON, HfTaO, HITiO, HfZrO, ZrO₂, Al₂O₃, or a combination thereof. However, the inventive concepts are not limited thereto.

A plurality of second insulating patterns 432 may extend in the second horizontal direction (the Y direction) on the plurality of first insulating patterns 422, and the channel layer 430 may be arranged between two adjacent second insulating patterns 432 among the plurality of second insulating patterns 432. In addition, between the two adjacent second insulating patterns 432, a first buried layer 434 and a second buried layer 436 may be arranged in a space between two adjacent channel layers 430. The first buried layer 434 may be arranged at a bottom of the space between the two adjacent channel layers 430, and the second buried layer 436 may be formed on the first buried layer 434 to fill the remaining portion of the space between the two adjacent channel layers 430. A top surface of the second buried layer 436 may be at the same level as a top surface of the channel layer 430 to cover a top surface of the gate electrode 440. Alternatively, the plurality of second insulating patterns 432 may be formed as a material layer continuous to the plurality of first insulating patterns 422, or the second buried layer 436 may be formed as a material layer continuous to the first buried layer 434.

A capacitor contact 460 may be arranged on the channel layer 430. The capacitor contacts 460 may be arranged to vertically overlap the channel layers 430, and may be arranged in a matrix to be apart from one another in the first horizontal direction (the X direction) and the second horizontal direction (the Y direction). For example, the capacitor contact 460 may include doped polysilicon, Al, Cu, Ti, Ta, Ru, W, Mo, Pt, Ni, Co, TiN, TaN, WN, NbN, TiAl, TIAIN, TiSi, TiSiN, TaSi, TaSIN, RuTiN, NiSi, CoSi, IrOₓ, RuOₓ, or a combination thereof. However, the inventive concepts are not limited thereto. The upper insulating layer 462 may surround a sidewall of the capacitor contact 460 on the plurality of second insulating patterns 432 and the second buried layer 436.

An etching stop layer 470 may be arranged on the upper insulating layer 462, and a capacitor structure 480 may be arranged on the etching stop layer 470. The capacitor structure 480 may include a lower electrode 482, a capacitor dielectric layer 484, and an upper electrode 486. The upper electrode 486 may form a stacked structure including a metallic electrode layer 486a, a lower conductive semiconductor layer 486b, and an upper conductive semiconductor layer 486c.

The lower electrode 482 may be electrically connected to a top surface of the capacitor contact 460 through the etching stop layer 470. The lower electrode 482 may be formed as a pillar type extending in the third direction (the Z direction). However, the inventive concepts are not limited thereto. In some example embodiments, the lower electrodes 482 may be arranged to vertically overlap the capacitor contacts 460, and may be arranged in a matrix to be apart from one another in the first horizontal direction (the X direction) and the second horizontal direction (the Y direction). Alternatively, a landing pad (not shown) may be further arranged between the capacitor contact 460 and the lower electrode 482 so that the lower electrode 482 may be arranged in a hexagonal shape.

The lower electrode 482, the capacitor dielectric layer 484, and the upper electrode 486 may be the lower electrode 210, the capacitor dielectric layer 220, and the upper electrode 230 illustrated in FIGS. 12A to 12D. The metallic electrode layer 486a, the lower conductive semiconductor layer 486b, and the upper conductive semiconductor layer 486c may be the metallic electrode layer 232, the lower conductive semiconductor layer 234, and the upper conductive semiconductor layer 236 illustrated in FIGS. 12A to 12D.

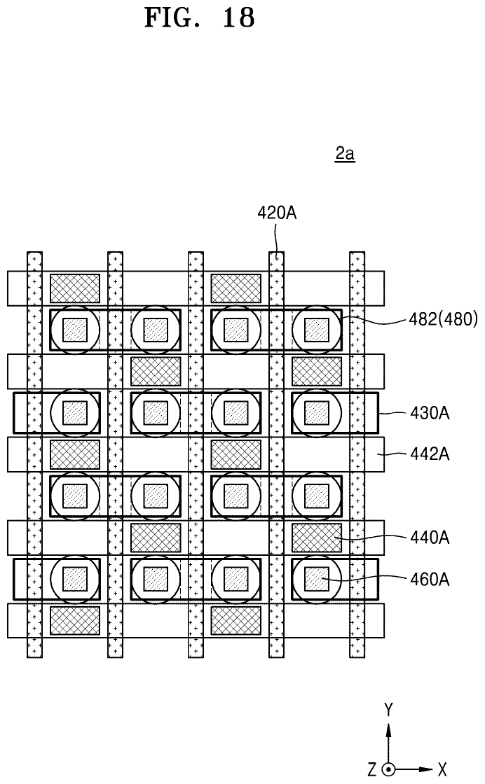

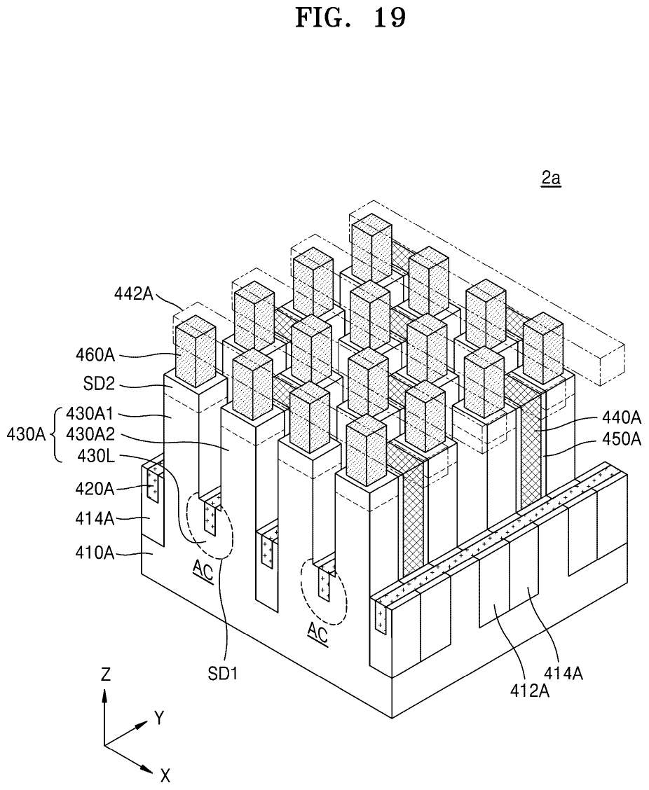

FIG. 18 is a layout diagram illustrating a semiconductor memory device 2a according to some example embodiments, and FIG. 19 is a perspective view illustrating a semiconductor memory device 2a.

Referring to FIGS. 18 and 19, the semiconductor memory device 2a may include a substrate 410A, a plurality of first conductive lines 420A, a channel structure 430A, a contact gate electrode 440A, a plurality of second conductive lines 442A, and a capacitor structure 480. The semiconductor memory device 2a may be a memory device including a VCT.

A plurality of active regions AC may be defined in the substrate 410A by a first device isolation layer 412A and a second device isolation layer 414A. The channel structure 430A may be arranged in each active region AC and may include a first active pillar 430A1 and a second active pillar 430A2 extending in the vertical direction, and a connection portion 430L connected to a bottom of the first active pillar 430A1 and a bottom of the second active pillar 430A2. A first source/drain region SD1 may be arranged in the connection portion 430L, and a second source/drain region SD2 may be arranged on the first and second active pillars 430A1 and 430A2. Each of the first active pillar 430A1 and the second active pillar 430A2 may constitute an independent unit memory cell.

The plurality of first conductive lines 420A may extend in a direction crossing the plurality of active regions AC, for example, in the second horizontal direction (the Y direction). One of the plurality of first conductive lines 420A may be arranged on the connection portion 430L between the first active pillar 430A1 and the second active pillar 430A2 and may be arranged on the first source/drain region SD1. The other first conductive line 420A adjacent to the one first conductive line 420A may be arranged between two channel structures 430A. One of the plurality of first conductive lines 420A may function as a common bit line included in two unit memory cells including the first active pillar 430A1 and the second active pillar 430A2 arranged on both sides of the one first conductive line 420A.

One contact gate electrode 440A may be arranged between two channel structures 430A adjacent to each other in the second horizontal direction (the Y direction). For example, the contact gate electrode 440A may be arranged between the first active pillar 430A1 included in one channel structure 430A and the second active pillar 430A2 of the channel structure 430A adjacent thereto and may be shared by the first active pillar 430A1 and the second active pillar 430A2 arranged on both sidewalls thereof. A gate insulating layer 450A may be arranged between the contact gate electrode 440A and the first active pillar 430A1 and between the contact gate electrode 440A and the second active pillar 430A2. A plurality of second conductive lines 442A may extend in the first horizontal direction (the X direction) on a top surface of the contact gate electrode 440A. The plurality of second conductive lines 442A may function as word lines of the semiconductor memory device 2a.

A capacitor contact 460A may be arranged on the channel structure 430A. The capacitor contact 460A may be arranged on the second source/drain region SD2 and the capacitor structure 480 may be arranged on the capacitor contact 460A. The capacitor structure 480 may be any one of the capacitor structures 200 and 200a described with reference to FIGS. 12A to 13D. The semiconductor memory device 2a may further include the wiring contact plug 310 and the wiring line 320 illustrated in FIGS. 12A to 13D.

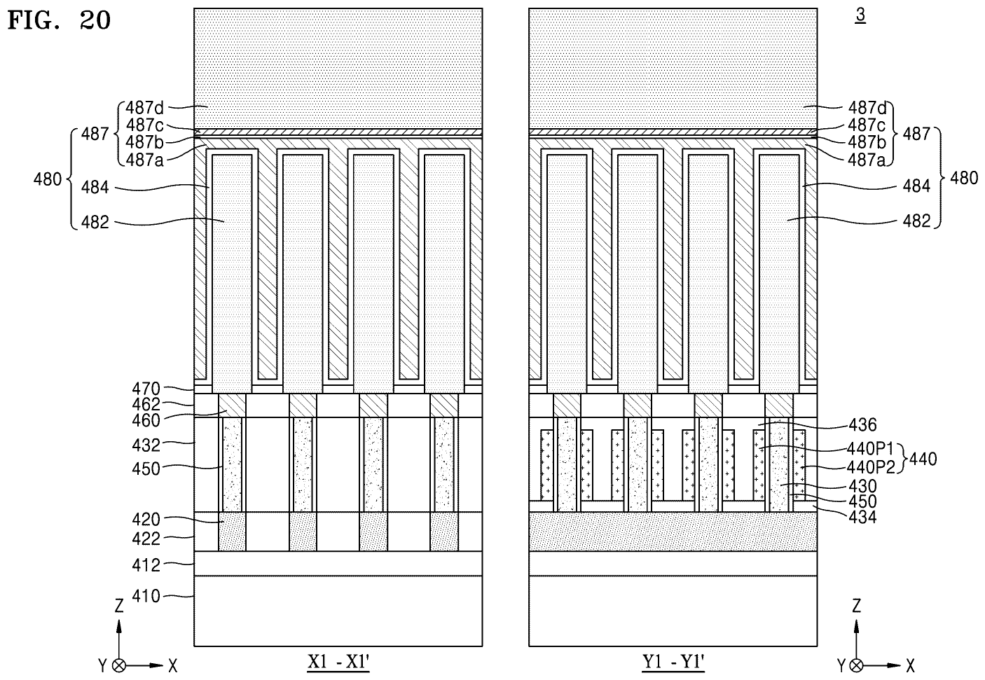

FIG. 20 is a cross-sectional view taken along line X1-X1′ and line Y1-Y1′ of FIG. 16.

Referring to FIG. 20, the semiconductor memory device 3 may include a substrate 410, a plurality of first conductive lines 420, a channel layer 430, a gate electrode 440, a gate insulating layer 450, and a capacitor structure 480. The semiconductor memory device 3 may be a memory device including a VCT.

A lower insulating layer 412 may be arranged on the substrate 410, and the plurality of first conductive lines 420 may be apart from one another in the first horizontal direction (the X direction) and may extend in the second horizontal direction (the Y direction) on the lower insulating layer 412. A plurality of first insulating patterns 422 may be arranged on the lower insulating layer 412 to fill spaces among the plurality of first conductive lines 420. The plurality of first insulating patterns 422 may extend in the second horizontal direction (the Y direction), and top surfaces of the plurality of first insulating patterns 422 may be at the same level as top surfaces of the plurality of first conductive lines 420. The plurality of first conductive lines 420 may function as bit lines of the semiconductor memory device 3.

The channel layer 430 may be arranged on the plurality of first conductive lines 420 in a matrix to be apart from one another in the first horizontal direction (the X direction) and the second horizontal direction (the Y direction).

The gate electrode 440 may extend in the first horizontal direction (the X direction) on both sidewalls of the channel layer 430. The gate electrode 440 may include a first sub-gate electrode 440P1 facing a first sidewall of the channel layer 430 and a second sub-gate electrode 440P2 facing a second sidewall opposite the first sidewall of the channel layer 430. As one channel layer 430 is arranged between the first sub-gate electrode 440P1 and the second sub-gate electrode 440P2, the semiconductor memory device 3 may have a dual gate transistor structure. However, the inventive concepts are not limited thereto, and a single gate transistor structure may be implemented by omitting the second sub-gate electrode 440P2 and forming only the first sub-gate electrode 440P1 facing the first sidewall of the channel layer 430.

The gate insulating layer 450 may surround sidewalls of the channel layer 430, and may be between the channel layer 430 and the gate electrode 440.

A plurality of second insulating patterns 432 may extend in the second horizontal direction (the Y direction) on the plurality of first insulating patterns 422, and the channel layer 430 may be arranged between two adjacent second insulating patterns 432 among the plurality of second insulating patterns 432. In addition, between the two adjacent second insulating patterns 432, a first buried layer 434 and a second buried layer 436 may be arranged in a space between two adjacent channel layers 430.

A capacitor contact 460 may be arranged on the channel layer 430. The capacitor contact 460 may be arranged to vertically overlap the channel layer 430, and may be arranged in a matrix form spaced apart from each other in the first horizontal direction (X direction) and the second horizontal direction (Y direction).

An etching stop layer 470 may be arranged on the upper insulating layer 462, and a capacitor structure 480 may be arranged on the etching stop layer 470. The capacitor structure 480 may include a lower electrode 482, a capacitor dielectric layer 484, and an upper electrode 487. The upper electrode 487 may form a stacked structure including a metallic electrode layer 487a, a metal compound layer 487b, a lower conductive semiconductor layer 487c, and an upper conductive semiconductor layer 487d.

The lower electrode 482 may be electrically connected to a top surface of the capacitor contact 460 through the etching stop layer 470. The lower electrode 482, the capacitor dielectric layer 484, and the upper electrode 487 may be the lower electrode 210, the capacitor dielectric layer 220, and the upper electrode 230a illustrated in FIGS. 13A to 13D. The metallic electrode layer 487a, the metal compound layer 487b, the lower conductive semiconductor layer 487c, and the upper conductive semiconductor layer 487d may be the metallic electrode layer 232a, the metal compound layer 233, the lower conductive semiconductor layer 234b, and the upper conductive semiconductor layer 236 illustrated in FIGS. 13A to 13D.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

While the inventive concepts have been particularly shown and described with reference to some example embodiments thereof, it will be understood that various changes in form and details may be made therein without departing from the spirit and scope of the following claims.

What is claimed is:

1. A method of manufacturing a semiconductor memory device, the method comprising:
preparing a substrate including a device isolation layer and a plurality of active regions, the plurality of active regions defined by the device isolation layer;
forming, over the substrate, a plurality of lower electrodes electrically connected to the plurality of active regions;
forming a capacitor dielectric layer on the plurality of lower electrodes;
forming an upper electrode on the capacitor dielectric layer;
forming a cover insulating layer covering the upper electrode; and
forming a wiring contact plug connected to the upper electrode through the cover insulating layer, the forming of the upper electrode on the capacitor dielectric layer further including
forming a metallic electrode layer covering the capacitor dielectric layer and filling all spaces among the plurality of lower electrodes;
forming a lower conductive semiconductor layer covering the metallic electrode layer; and
forming an upper conductive semiconductor layer covering the lower conductive semiconductor layer, and
each of the lower conductive semiconductor layer and the upper conductive semiconductor layer include a group IV compound semiconductor material including germanium (Ge), and a Ge concentration of the lower conductive semiconductor layer is lower than a Ge concentration of the upper conductive semiconductor layer.

2. The method of claim 1, wherein
a bottom surface of the cover insulating layer directly contacts a top surface of the upper conductive semiconductor layer, and
the wiring contact plug extends to the upper conductive semiconductor layer through the cover insulating layer.

3. The method of claim 2, wherein the wiring contact plug extends into the upper conductive semiconductor layer and does not extend to the lower conductive semiconductor layer.

4. The method of claim 2, wherein the wiring contact plug extends from a top surface of the upper conductive semiconductor layer into the upper conductive semiconductor layer by half a thickness of the upper conductive semiconductor layer or less.

5. The method of claim 1, wherein a thickness of the lower conductive semiconductor layer is less than a thickness of the metallic electrode layer on the capacitor dielectric layer.

6. The method of claim 5, wherein the thickness of the lower conductive semiconductor layer is 5% or less of a thickness of the upper conductive semiconductor layer.

7. The method of claim 5, wherein the thickness of the lower conductive semiconductor layer is equal to or greater than a thickness of the capacitor dielectric layer.

8. The method of claim 1, wherein the metallic electrode layer comprises a noble metal.

9. The method of claim 8, wherein the metallic electrode layer comprises ruthenium (Ru).

10. The method of claim 1, wherein each of the lower conductive semiconductor layer and the upper conductive semiconductor layer comprises silicon-germanium.

11. The method of claim 1, wherein
the upper electrode further comprises a metal compound layer between the metallic electrode layer and the lower conductive semiconductor layer and including metal germanide or metal silicide, and
a thickness of the metal compound layer is less than a thickness of the metallic electrode layer.

12. A method of manufacturing a semiconductor memory device, the method comprising:
preparing a substrate including a device isolation layer and a plurality of active regions, the plurality of active regions defined by the device isolation layer;
forming a plurality of word lines extending in a first horizontal direction across the plurality of active regions;
forming a plurality of bit lines on the plurality of active regions and extending in a second horizontal direction orthogonal to the first horizontal direction;
forming a plurality of buried contacts filling lower portions of spaces among the plurality of bit lines and connected to the plurality of active regions;
forming a plurality of landing pads filling upper portions of spaces among the plurality of bit lines and extending onto the plurality of bit lines;
forming a plurality of lower electrodes connected to the plurality of landing pads;
forming a capacitor dielectric layer on the plurality of lower electrodes;
forming an upper electrode on the capacitor dielectric layer;
forming a cover insulating layer covering the upper electrode; and
forming a wiring contact plug connected to the upper electrode through the cover insulating layer, the forming of the upper electrode on the capacitor dielectric layer further including
forming a metallic electrode layer covering the capacitor dielectric layer, filling all spaces among the plurality of lower electrodes, and including a noble metal;
forming a lower conductive semiconductor layer covering the metallic electrode layer; and
forming an upper conductive semiconductor layer covering the lower conductive semiconductor layer, and
each of the lower conductive semiconductor layer and the upper conductive semiconductor layer including silicon-germanium, and a Ge concentration of the lower conductive semiconductor layer is lower than a Ge concentration of the upper conductive semiconductor layer.

13. The method of claim 12, wherein a thickness of the lower conductive semiconductor layer is less than each of a thickness of the upper conductive semiconductor layer and a thickness of the metallic electrode layer on the capacitor dielectric layer and is equal to or greater than a thickness of the capacitor dielectric layer.

14. The method of claim 12, wherein
a bottom surface of the cover insulating layer directly contacts a top surface of the upper conductive semiconductor layer, and
the wiring contact plug extends into the upper conductive semiconductor layer through the cover insulating layer and does not extend to the lower conductive semiconductor layer.

15. The method of claim 12, wherein
the metallic electrode layer comprises Ru, and the upper electrode further comprises a metal compound layer including ruthenium germanide or ruthenium silicide, the metal compound layer interposed between the metallic electrode layer and the lower conductive semiconductor layer, and
a thickness of the metal compound layer is less than a thickness of the metallic electrode layer.

16. The method of claim 12, wherein
the lower conductive semiconductor layer is formed under a first deposition temperature condition, and
the upper conductive semiconductor layer is formed at a second deposition temperature, the second deposition temperature being a same temperature or lower than the first deposition temperature.

17. The method of claim 16, wherein the first deposition temperature is a same temperature as the second deposition temperature.

18. A method of manufacturing a semiconductor memory device, the method comprising:
preparing a substrate including a device isolation layer and a plurality of active regions, the plurality of active regions defined by the device isolation layer;
forming a plurality of word lines extending in a first horizontal direction across the plurality of active regions;
forming a plurality of bit lines extending in a second horizontal direction orthogonal to the first horizontal direction on the plurality of word lines and a plurality of direct contact conductive patterns connecting the plurality of bit lines to the plurality of active regions;
forming a plurality of buried contacts filling lower portions of spaces among the plurality of bit lines and connected to the plurality of active regions;
forming a landing pad material layer covering the plurality of bit lines;
removing part of the landing pad material layer to define a recess and form the plurality of landing pads apart from each other with the recess therebetween and connected to the plurality of buried contacts;
forming an insulating layer filling the recess;
forming a plurality of capacitor structures connected to the plurality of landing pads;
forming a cover insulating layer covering the plurality of capacitor structures; and
forming a wiring contact plug passing through the cover insulating layer, the forming of the plurality of capacitor structures further including
forming a plurality of lower electrodes connected to the plurality of landing pads on the insulating layer and the plurality of landing pads;
forming a capacitor dielectric layer on the plurality of lower electrodes; and
forming, on the capacitor dielectric layer, an upper electrode connected to the wiring contact plug, the forming, on the capacitor dielectric layer, of the upper electrode further including
forming a metallic electrode layer covering the capacitor dielectric layer, filling all spaces among the plurality of lower electrodes, and including ruthenium (Ru);
forming a lower conductive semiconductor layer covering the metallic electrode layer; and
forming an upper conductive semiconductor layer covering the lower conductive semiconductor layer, each of the lower conductive semiconductor layer and the upper conductive semiconductor layer including silicon-germanium, and a Ge concentration of the lower conductive semiconductor layer is lower than a Ge concentration of the upper conductive semiconductor layer, and
a thickness of the lower conductive semiconductor layer is less than each of a thickness of the upper conductive semiconductor layer and a thickness of the metallic electrode layer on the capacitor dielectric layer and is equal to or greater than a thickness of the capacitor dielectric layer.

19. The method of claim 18, wherein
a bottom surface of the cover insulating layer directly contacts a top surface of the upper conductive semiconductor layer, and
the wiring contact plug extends from a top surface of the upper conductive semiconductor layer into the upper conductive semiconductor layer by half a thickness of the upper conductive semiconductor layer or less and does not extend to the lower conductive semiconductor layer.

20. The method of claim 18, wherein
the upper electrode further comprises a metal compound layer including ruthenium germanide or ruthenium silicide, the metal compound layer interposed between the metallic electrode layer and the lower conductive semiconductor layer, the lower conductive semiconductor layer is formed under a first deposition temperature condition, and
the upper conductive semiconductor layer is formed at a second deposition temperature, the second deposition temperature being a same temperature or lower than the first deposition temperature.
